(19) United States
(12) Patent Application Publication
(10) Pub. No.: US 2009/0086551 A1
(43) Pub. Date: Apr. 2, 2009

(54) Semiconductor device

(75) Inventors: Akira Ide, Tokyo (JP); Yasuhiro Takai, Tokyo (JP); Riichiro Takemura, Los Angeles, CA (US); Tomonori Sekiguchi, Tama (JP)

Correspondence Address: FOLEY AND LARDNER LLP;SUITE 500, 3000 K STREET NW, WASHINGTON, DC, 20007, US

(73) Assignee: Elpida Memory, Inc.

(21) Appl. No.: 12/285,204

(22) Filed: Sep. 30, 2008

(30) Foreign Application Priority Data
Oct. 1, 2007 (JP) 2007-257467

(51) Int. Cl. G11C 7/00; G06F 11/00; G06F 11/10; G11C 8/00

(52) U.S. Cl. 365/189.03; 365/189.011; 714/799; 714/807; 365/230.02; 365/230.03; 714/E11.001; 714/E11.032

(57) ABSTRACT

Disclosed is a semiconductor device in which In case a data group output from a first output pin in a first word configuration is output from the first output pin and a second output pin in a second word configuration, and a data group output from a third output pin in a first word configuration is output from the third output pin and a fourth output pin in a second word configuration, the second output pin is arranged adjacent to the first output pin, and the fourth output pin is arranged adjacent to the third output pin.

### REFERENCE TO RELATED APPLICATION

This application is based upon and claims the benefit of the priority of Japanese patent application No. 2007-257467, filed on Oct. 1, 2007, the disclosure of which is incorporated herein in its entirety by reference thereto.

### FIELD OF THE INVENTION

This invention relates to a semiconductor device, and in particular to a configuration of a data output path of a memory array.

### BACKGROUND OF THE INVENTION

With a high speed transmission line, there is a possibility of an error being generated in transfer data due to effects such as noise from outside. Usually, in a system in which data is transferred on a high speed transmission line, error detection is implemented using a Cyclic Redundancy Check (CRC) and when an error is detected, data is re-transferred, thus improving reliability of data being transferred.

Data transfer speed between a DRAM (Dynamic Random Access Memory) and a memory controller is also being speed up, and there is a possibility of an error being generated, similar to a high speed communication line.

### SUMMARY OF THE DISCLOSURE

The following analyses are given by the present invention.

In a DRAM, a method may be conceived in which an error is detected by CRC and re-transmission processing is performed, similar to a case of the communication line. However, in order to do so, there is a necessity to generate CRC code inside the DRAM.

CRC code is generated by selecting a plurality of bits from transfer data and obtaining an exclusive OR thereof.

In a DRAM, in manufacturing one chip, handling of multiple types of word configuration, for example, 4 bit (×4 configuration) and 8-bit (×8 configuration) input/output data pins, is desirable.

In the ×8 configuration, memory array area assigned to one output pin is halved as compared the ×4 configuration. For example, data assigned to an output pin DQ0 in the ×4 configuration is assigned to DQ4 as well as DQ0 in the ×8 configuration.

In case the number of the data output to DQ4 in the ×8 configuration and the number of the data of DQ0 in the ×4 configuration are different, and in case memory arrays storing data of an identical data number in the ×4 configuration and the ×8 configuration are different, the following problems occur.

In case of encoding such as in CRC, a relationship between each CRC bit and data bit is determined uniquely. For example, in case 8-bit CRC bits C[7:0] are attached with respect to 32-bit data bits D[39:8], using as a generator polynomial:

G(x)=x̂8+x̂2+x+1

an expression is in the form of exclusive ORs of specific bits among 32 bits, as in

C[7]=D[13]+D[14]+D[15]+D[19]+D[21]+D[23]+D[25]+D[26]+D[28]+D[30]+D[35]+D[37]+D[38]

Since this equation is the same for the ×4 configuration and the ×8 configuration, when output pins at which respective data bits are output change, if array locations storing data bits change in response thereto, a plurality of CRC encoding circuits have to be provided, according to the word configuration, thereby leading to an increase in chip area.

In case of using a common encoding circuit, in order to handle a plurality of word configurations, it is necessary to configure a data bus for each word configuration and hence there are problems in that the number of data buses inside a chip increases, wiring length becomes long, and that operating speed and power consumption increase.

We have recognized that such a semiconductor device that performs encoding processing such as CRC and is able to suppress chip area increase due to encoding circuit in case of handling a plurality of word configurations is desired.

The invention disclosed in the present application may be configured as follow. In the description below, reference symbols within parentheses following elements are added only to facilitate understanding, and clearly are not to be interpreted as limiting the scope of the invention.

In the present invention, there is provided a semiconductor device having an encoding circuit, wherein, in a first word configuration, first and second data are output from a first output pin, and third and fourth data are output from a second output pin; in a second word configuration, the first data is output from the first output pin, the second data is output from a third output pin, the third data is output from the second output pin, and the fourth data is output from a fourth output pin; and wherein distance between the second output pin and the first output pin is shorter than distance between the second output pin and the third output pin, and distance between the fourth output pin and the third output pin is shorter than distance between the fourth output pin and the first output pin.

In the present invention, there is provided first to fourth output pins (D0, D1, D2, D3). In the first word configuration, a first data group is output from the first output pin (DQ0); in the second word configuration, second and third data groups are output respectively from the first output pin (DQ0) and the second output pin (DQ1); in the first word configuration, a fourth data group is output from the third output pin (DQ2); and in the second word configuration, fifth and sixth data groups are output respectively from the third output pin (DQ2) and the fourth output pin (DQ3). There are also provided a first encoding circuit which receives the first data group and the second data group, and a second encoding circuit which receives the fourth data group and the fifth data group. The distance between the second output pin and the first output pin is shorter than distance between the second output pin and the third output pin, and the distance between the fourth output pin and the third output pin is shorter than the distance between the fourth output pin and the first output pin. In the present invention, the first, the second, and the third data groups are read from a first memory cell array, and the fourth, the fifth, and the sixth data groups are read out from a second memory cell array.

In an embodiment of the present invention, there is provided a semiconductor device including: a first memory array having a plurality of memory cells arranged at prescribed intersections of a plurality of word lines and a plurality of bit lines;

first and second data buses output from the first memory array;

a first encoding circuit having input connected to the first and second data buses;

a second memory array having a plurality of memory cells arranged at prescribed intersections of a plurality of word lines and a plurality of bit lines;

third and fourth data buses output from the second memory array; and

a second encoding circuit having input connected to the third and fourth data buses.

In a first word configuration, data of the first and second data buses are output from a first output pin, and

data of the third and fourth data buses are output from a second output pin.

In a second word configuration,

data of the first data bus are output from the first output pin,

data of the second data bus are output from the third output pin,

data of the third data bus are output from the second output pin, and

data of the fourth data bus are output from the fourth output pin.

In the semiconductor device according to an embodiment of the present invention, there are provided a third encoding circuit and a fourth encoding circuit. The first encoding circuit produces first, second, third, and fourth codes, the second encoding circuit produces fifth, sixth, seventh, and eighth codes, the third encoding circuit receives the first, second, seventh, and eighth codes, and produces first and second error detection codes, and the fourth encoding circuit receives the third, fourth, fifth, and sixth codes, and produces third and fourth error detection codes. In the first word configuration, the first and second error detection codes are output from the first output pin, and the third and fourth error detection codes are output from the second output pin. In the second word configuration, the first error detection code is output from the first output pin, the second error detection code is output from the third output pin, the third error detection code is output from the second output pin, and the fourth error detection code is output from the fourth output pin.

In the semiconductor device according to an embodiment of the present invention, there are provided a third encoding circuit, a fourth encoding circuit, and fifth and sixth output pins. The first encoding circuit produces first, second, third, and fourth codes, the second encoding circuit produces fifth, sixth, seventh, and eighth codes, the third encoding circuit receives the first, second, seventh, and eighth codes, and produces first and second error detection codes, and the fourth encoding circuit receives the third, fourth, fifth, and sixth codes, and produces third and fourth error detection codes. In the first word configuration, the first, second, third, and fourth error detection codes are output from the fifth output pin. In the second word configuration, the first and second error detection codes are output from the fifth output pin, and the third and fourth error detection codes are output from the sixth output pin.

In the semiconductor device according to an embodiment of the present invention, the first and second encoding circuits respectively have a switch for switching an output destination of an encoding operation result by a selection signal corresponding to the first or second word configuration.

In the semiconductor device according to an embodiment of the present invention, distance between the third output pin and the first output pin is shorter than distance between the third output pin and the second output pin, and distance between the fourth output pin and the second output pin is shorter than distance between the fourth output pin and the first output pin.

In the semiconductor device according to an embodiment of the present invention, there are also provided fifth and sixth data buses output from the first memory array and input to the first encoding circuit. In the first word configuration, data are output in an order of, from the first output pin, data of the first data bus, data of the second data bus, data of the fifth data bus, and data of the sixth data bus. In the second word configuration, data are output in the order of, from the first output pin, data of the first data bus and data of the sixth data bus, and data are output in the order of, from the third output pin, data of the second data bus and data of the fifth data bus.

In the semiconductor device according to an embodiment of the present invention, there are also provided seventh and eighth data buses output from the second memory array and input to the second encoding circuit. In the first word configuration, data are output in the order of, from the second output pin, data of the third data bus, data of the fourth data bus, data of the fifth data bus, and data of the sixth data bus. In the second word configuration, data are output in the order of, from the second output pin, data of the third data bus and data of the eighth data bus, and data are output in the order of, from the fourth output pin, data of the fourth data bus and data of the seventh data bus.

In the semiconductor device according to an embodiment of the present invention, there are also provided a third encoding circuit and a fourth encoding circuit. The first encoding circuit produces first, second, third, and fourth codes, the second encoding circuit produces fifth, sixth, seventh, and eighth codes, the third encoding circuit receives the first, second, seventh, and eighth codes, and produces first and second error detection codes, and the fourth encoding circuit receives the third, fourth, fifth, and sixth codes, and produces third and fourth error detection codes. In the first word configuration, the first and second error detection codes are output from the first output pin, and the third and fourth error detection codes are output from the second output pin. In the second word configuration, the first error detection code is output from the first output pin, the second error detection code is output from the second output pin, the third error detection code is output from the third output pin, and the fourth error detection code is output from the fourth output pin.

In the semiconductor device according to an embodiment of the present invention, there are also provided fifth and sixth data buses output from the first memory array and input to the first encoding circuit. In the first word configuration, data are output from the first output pin in an order of:

data of the first data bus;

data of the second data bus;

data of the fifth data bus; and

data of the sixth data bus. In the second word configuration, data are output from the first output pin in an order of:

data of the first data bus; and

data of the fifth data bus; and data are output from the third output pin in an order of:

data of the second data bus;

and data of the sixth data bus.

In the semiconductor device according to an embodiment of the present invention, there are also provided seventh and eighth data buses output from the second memory array and input to the second encoding circuit. In the first word configuration, data are output from the second output pin in an order of:

data of the third data bus;

data of the fourth data bus;

data of the seventh data bus; and

data of the eighth data bus. In the second word configuration, data are output from the second output pin in an order of:

data of the third data bus; and

data of the seventh data bus; and

data are output from the fourth output pin in an order of:

data of the fourth data bus; and

data of the eighth data bus.

In an embodiment of the present invention, there is provided a semiconductor device handling the first word configuration and the second word configuration including: a first data line for transferring data read from a memory cell array, and a first CRC encoding circuit which receives a signal of the first data line, a first switch for outputting first and second CRC intermediate calculation results output from the first CRC encoding circuit, and the first CRC intermediate calculation result, to the first data bus, a second switch for outputting the second CRC intermediate calculation result to the first data bus, and a second CRC encoding circuit which receives the first data bus.

In an embodiment of the present invention, there is provided a semiconductor device including:

a first encoding circuit (CRC1L) having input of data read from a plurality of memory banks (BANK0L-BANK7L) of the first memory array, the data being multiplexed by a first multiplexer (MUX8), to perform an operation of encoding for error detection,

a second encoding circuit (CRC1R) having input of data read from a plurality of memory banks (BANK0R-BANK7R) of the second memory array, the data being multiplexed by a second multiplexer (MUX8), to perform an operation of encoding for error detection,

a third encoding circuit (CRC2L) which receives operation results of the first encoding circuit and the second encoding circuit and generates first and second error detection codes,

a fourth encoding circuit (CRC2R) which receives operation results of the second encoding circuit and the first encoding circuit and generates third and fourth error detection codes,

first and second output buffers (FIFO) having inputs commonly connected to output of the first multiplexer (MUX8) and output of the third encoding circuit (CRC2L), and having outputs respectively connected to first and second output terminals (DQ0 and DQ1) corresponding to the first memory array side, and

third and fourth output buffers (FIFO) having inputs commonly connected to output of the second multiplexer and output of the fourth encoding circuit (CRC2R), and having output respectively connected to third and fourth output terminals (DQ2 and DQ4) corresponding to the second memory array side.

The first and second data output in sequence from the first output terminal (DQ0) in the first word configuration are output in parallel from the first output terminal (DQ0) and the second output terminal (DQ1) in the second word configuration. The third and fourth data output in sequence from the third output terminal (DQ2) in the first word configuration are output in parallel from the third output terminal (DQ2) and the fourth output terminal (DQ3) in the second word configuration. The first and second error detection codes output in sequence from the first output terminal (DQ0), and the third and fourth error detection codes output in sequence from the third output terminal (DQ2), in the first word configuration, are output in parallel from the first, second, third, and fourth output terminals (DQ0, DQ1, DQ2, and DQ3) in the second word configuration.

In an embodiment of the present invention, there is provided a semiconductor device including:

a first encoding circuit (CRC1L) having input of data read from the plurality of memory banks (BANK0L-BANK7L) of the first memory array, the data being multiplexed by the first multiplexer (MUX8), to perform an operation of encoding for error detection,

a second encoding circuit (CRC1R) having input of data read from the plurality of memory banks (BANK0R-BANK7R) of the second memory array, the data being multiplexed by the second multiplexer (MUX8), to perform an operation of encoding for error detection,

a third encoding circuit (CRC2) which receives operation results of the first encoding circuit and the second encoding circuit and generates first and second error detection codes,

first and second output buffers (FIFO) having inputs commonly connected to output of the first multiplexer (MUX8) and having outputs respectively connected to the first and second output terminals (DQ0 and DQ1) corresponding to the first memory array side,

third and fourth output buffers (FIFO) having inputs commonly connected to output of the second multiplexer (MUX8), and having outputs respectively connected to the third and fourth output terminals (DQ2 and DQ3) corresponding to the second memory array side, and

fifth and sixth output buffers (FIFO) having inputs commonly connected to output of the third encoding circuit (CRC2), and having outputs respectively connected to error detection code-dedicated first and second output terminals (DQC0 and DQC1), arranged between the first and second output terminals, and the third and fourth output terminals.

The first and second data output in sequence from the first output terminal (DQ0) in the first word configuration are output in parallel from the first output terminal (DQ0) and the second output terminal (DQ1) in the second word configuration. The third and fourth data output in sequence from the third output terminal (DQ2) in the first word configuration are output in parallel from the third output terminal (DQ2) and the fourth output terminal (DQ3) in the second word configuration. The first and second error detection codes output in sequence from the error detection code-dedicated first output terminal (DQ0) in the first word configuration, are output in parallel from the error detection code-dedicated first and second output terminals (DQC0 and DQC1) in the second word configuration.

According to the present invention, in a semiconductor device which outputs code (error correction code) for error detection, such as CRC or the like, together with data bits, by determining assignment of data terminals (DQ) in each word configuration corresponding to mapping of data output from the data terminals (DQ) in a plurality of word configurations, usage of a common CRC encoding circuit is made possible, in the plurality of word configurations, and it is possible to suppress extra routing of data wiring inside a chip and to achieve high speed operation and reduced area.

According to the present invention, by using a data mapping method corresponding to a specified pin assignment method, it is possible to realize sharing of the CRC encoding circuit and short data bus length.

Still other features and advantages of the present invention will become readily apparent to those skilled in this art from the following detailed description in conjunction with the accompanying drawings wherein only the preferred embodiments of the invention are shown and described, simply by way of illustration of the best mode contemplated of carrying out this invention. As will be realized, the invention is capable of other and different embodiments, and its several details are capable of modifications in various obvious respects, all without departing from the invention. Accordingly, the drawing and description are to be regarded as illustrative in nature, and not as restrictive.

### BRIEF DESCRIPTIONS OF THE DRAWINGS

FIGS. 1A and 1B show a data path oriented block diagram and a chip internal placement of a DRAM, in which a first exemplary embodiment of the present invention is applied.

FIGS. 2A and 2B show data output order of each output pin in the first exemplary embodiment of the present invention.

FIGS. 3A and 3B show data output order of each output pin for a 64-bit data group in the first exemplary embodiment.

FIGS. 4A and 4B show a generated data bit configuration example of CRC bits in case one generator polynomial is used.

FIGS. 5A and 5B show a configuration example in case the generated data bits of FIGS. 4A and 4B are divided into regions on the left and right of the chip.

FIG. 6 is a diagram showing a circuit configuration that obtains CRC intermediate calculation results of the left side region (LEFT) of the chip of FIGS. 5A and 5B.

FIG. 7 is a diagram showing a circuit configuration that obtains CRC intermediate calculation results of the right side region (RIGHT) of the chip of FIGS. 5A and 5B.

FIGS. 8A and 8B show a circuit configuration example that obtains CRC bits from CRC intermediate calculation results.

FIG. 9 is a diagram showing an operation waveform in an ×4 configuration of the present exemplary embodiment.

FIG. 10 is a diagram showing an operation waveform in an ×8 configuration of the present exemplary embodiment.

FIGS. 11A and 11B show a data system block diagram and a chip internal arrangement of a DRAM, in which a second exemplary embodiment is applied.

FIGS. 12A and 12B show data output order of each output pin in the second exemplary embodiment.

FIGS. 13A and 13B show data output order of each output pin for a 64-bit data group in the second exemplary embodiment.

FIGS. 14A and 14B show a configuration example in case the generated data bits of FIGS. 4A and 4B are divided into regions on the left and right of the chip.

FIG. 15 is a diagram showing a circuit configuration that obtains CRC intermediate calculation results of the left side region (LEFT) of the chip of FIGS. 13A and 13B.

FIG. 16 is a diagram showing a circuit configuration that obtains CRC intermediate calculation results of the right side region (RIGHT) of the chip of FIGS. 13A and 13B.

FIGS. 17A and 17B show a circuit configuration example that obtains CRC bits from CRC intermediate calculation results.

FIG. 18 is a diagram showing an operation waveform in an ×4 configuration of the present exemplary embodiment.

FIG. 19 is a diagram showing an operation waveform in an ×8 configuration of the present exemplary embodiment.

FIGS. 20A and 20B show a data system block diagram and a chip internal arrangement of a DRAM, in which a modified example of the first exemplary embodiment is applied.

FIG. 21 is a diagram showing a circuit configuration example that obtains CRC bits from CRC intermediate calculation results.

FIGS. 22A and 22B show data output order of each output pin in the modified example of the first exemplary embodiment.

FIG. 23 is a diagram showing an operation waveform in an ×4 configuration of the present exemplary embodiment.

FIG. 24 is a diagram showing an operation waveform in an ×8 configuration of the present exemplary embodiment.

FIGS. 25A and 25B show a data system block diagram and a chip internal arrangement of a DRAM, in which a modified example of the second exemplary embodiment is applied.

FIG. 26 is a diagram showing a circuit configuration example that obtains CRC bits from CRC intermediate calculation results.

FIGS. 27A and 27B show data output order of each output pin in the modified example of the second exemplary embodiment.

FIG. 28 is a diagram showing an operation waveform in an ×4 configuration of the present exemplary embodiment.

FIG. 29 is a diagram showing an operation waveform in an ×8 configuration of the present exemplary embodiment.

FIG. 30 is a diagram showing a configuration example of a memory bank region.

FIG. 31 is a diagram showing a configuration example of a memory cell array.

### PREFERRED MODES OF THE INVENTION

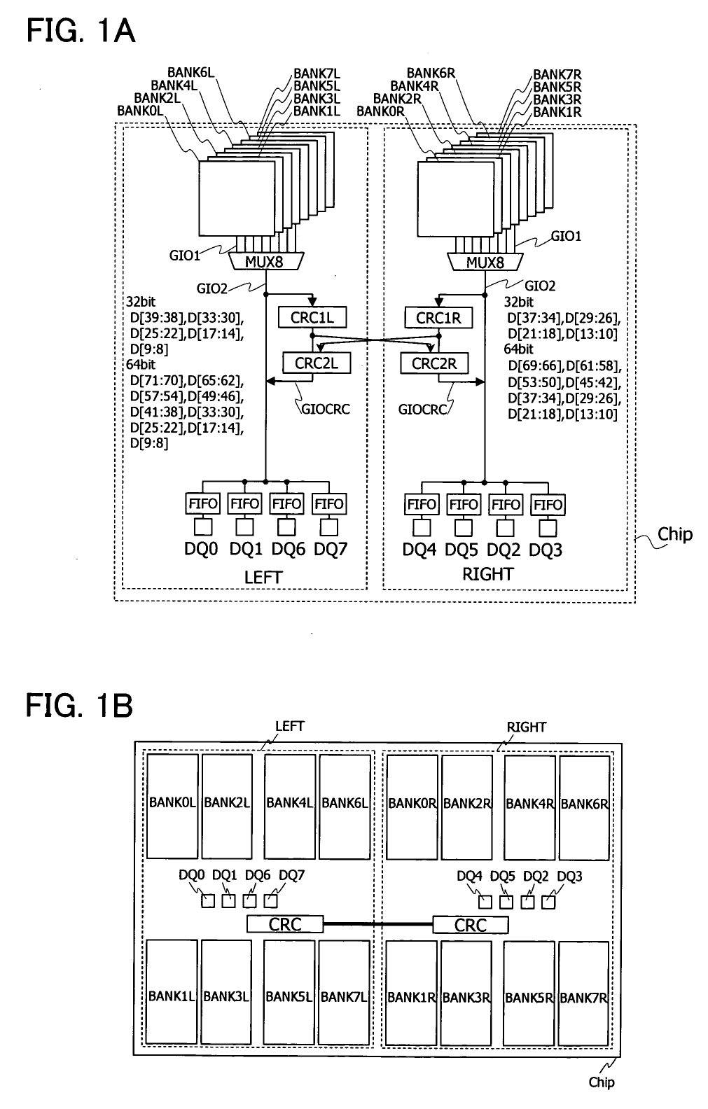

Preferred modes of the present invention will be described in detail, referring to the drawings. FIGS. 1A and 1B describe a first exemplary embodiment of the invention. FIGS. 1A and 1B are a block diagram showing a DRAM data bus configuration and a physical chip image.

In the present exemplary embodiment, a CRC encoding circuit is shared by a plurality of word configurations, chip area is reduced, and the arrangement of output pins is made such that the number of data buses inside a chip is reduced.

FIGS. 1A and 1B are diagrams which, for the same chip, show the block diagram and the physical chip image for describing a configuration of the chip realizing an ×4 configuration outputting 4 items of data and an ×8 configuration outputting 8 items of data, at one data output timing.

The chip includes a left side region (LEFT) and a right side region (RIGHT). In the left side region, DQ0, DQ1, DQ6, and DQ7 are arranged as output pins, and in case of the ×4 configuration, output pins DQ0 and DQ1 are used, and output pins DQ6 and DQ7 are not used in data output. In case of the ×8 configuration, all of the output pins DQ0, DQ1, DQ6, and DQ7 are used.

As shown in FIGS. 1A and 1B, in the present exemplary embodiment, the output pins DQ6 and DQ7 are arranged adjacent to the output pins DQ0 and DQ1. In a data output order described later, output data of the output pins DQ0 and DQ1 for the ×4 configuration are output in the ×8 configuration from the output pins DQ0, DQ1, DQ6, and DQ7. By this type of configuration, it is possible to share a CRC encoding circuit between the ×4 and the ×8 configurations.

In addition, since data output from the left side of the chip are output from output pins arranged on the left side of the chip, a data bus crossing from left to right of the chip is not necessary.

Half of the memory bank regions of each memory bank, BANK0L, BANK1L, BANK2L, BANK3L, BANK4L, BANK5L, BANK6L, and BANK7L are arranged in the left side region (LEFT) of the chip.

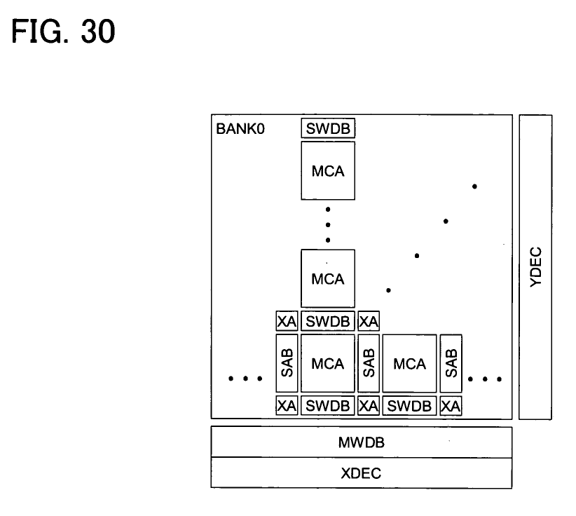

FIG. 30 shows a configuration of a memory bank. The memory bank region is formed of a plurality of memory cell array regions MCA.

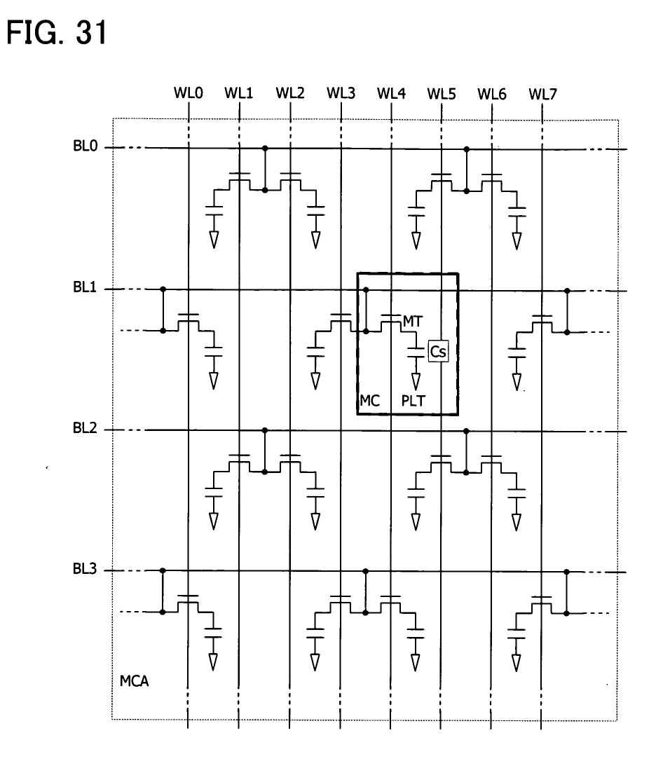

FIG. 31 shows a configuration example of a DRAM memory cell array. A memory cell MC is formed of a transistor MT and a capacitor Cs, one electrode thereof being commonly connected to those of capacitors of other memory cells.

As shown in FIG. 30, a subword driver block SWDB for driving a word line, a sense amplifier block SAB for amplifying a signal read on a bit line, and a cross areas XA in which control lines of the sub-word driver block and the sense amplifier blocks are driven, are arranged between memory cell arrays MCA.

As shown in FIG. 1A, in the left side region (LEFT) of the chip, a bank data output path GIO1 is connected to each memory bank BANK0L, BANK1L, BANK2L, BANK3L, BANK4L, BANK5L, BANK6L, and BANK7L, and the bank data output paths GIO1 are connected to a multiplexer MUX8.

Data output to the data output bus GIO1 are, in case of a 32 bit read chip:

data groups D[39:38], D[33:30], D[25:22], D[17:14], and D[9:8], and in case of a 64 bit read chip,

data groups D[71:70], D[65:62], D[57:54], D[49:46], D[41:38], D[33:30], D[25:22], D[17:14], and D[9:8].

In the present exemplary embodiment, since the same CRC encoding circuits are used for the ×4 configuration and the ×8 configuration, data numbers are the same for the ×4 configuration and the ×8 configuration.

The multiplexer MUX8, according to read command and input address, connects a bank data output path GIO1 from one memory bank selected among the 8 memory banks, and a common data output path GIO2.

The common data output path GIO2 is connected to input of a first CRC encoding circuit CRC1L. The common data output path GIO2 is connected to inputs to output buffers FIFO of:

output pins DQ0 and DQ1 in the ×4 configuration, and
output pins DQ0, DQ1, DQ6 and DQ7 in the ×8 configuration.

The output of the first CRC encoding circuit CRC1L is supplied to a second encoding circuit CRC2L in the left side region and a second encoding circuit CRC2R in the right side region.

A CRC code bit output path GIOCRC of the second CRC encoding circuit CRC2L, similar to the common data output path GIO2, is connected to inputs of output buffers FIFO of:

output pins DQ0 and DQ1 in the ×4 configuration, and
output pins DQ0, DQ1, DQ6 and DQ7 in the ×8 configuration.

In the same way, DQ2, DQ3, DQ4, and DQ5 are arranged as output pins in the right side region (RIGHT) of the chip. In the ×4 configuration the output pins DQ2 and DQ3 are used, and the output pins DQ4 and DQ5 are not used as data output. In case of the ×8 configuration, all of the output pins DQ2, DQ3, DQ4, and DQ5 are used.

The output pins DQ4 and DQ5 are arranged adjacent to the output pins DQ2 and DQ3. This is because, similar to the left side region (LEFT) of the chip, in data output order described later, output data of the output pins DQ2 and DQ3 in the ×4 configuration are output from DQ2, DQ3, DQ4, and DQ5 in the ×8 configuration.

In the present exemplary embodiment, with this type of configuration, the CRC encoding circuits can be shared between a plurality of word configurations, and a data bus crossing between left and right of the chip is not necessary.

Half of the memory bank regions of each memory bank, BANK0R, BANK1R, BANK2R, BANK3R, BANK4R, BANK5R, BANK6R, and BANK7R are arranged in the right side region (RIGHT) of the chip.

A bank data output path GIO1 is connected to each memory bank, and the bank data output path GIO1 is connected to a multiplexer MUX8.

Data output to the data output bus GIO1 are, in case of a 32 bit read chip,

D[37:34], D[29:26], D[21:18], and D[13:10], and in case of a 64 bit read chip,

D[69:66], D[61:58], D[53:50], D[45:42], D[37:34], D[29:26], D[21:18], and D[13:10].

Similar to the left side region (LEFT) of the chip, since the same CRC encoding circuits are used for the ×4 configuration and the ×8 configuration, data numbers are the same for the ×4 configuration and the ×8 configuration.

In the right side region (RIGHT) of the chip, the multiplexer MUX8, according to read command and input address, connects a bank data output path GIO1 from one memory bank and a common data output path GIO2.

The common data output path GIO2 is supplied to a first CRC encoding circuit CRC1R. The common data output path GIO2 is connected to inputs of output buffers FIFO

of: output pins DQ2 and DQ3 for the ×4 chip, and

of output pins DQ2, DQ3, DQ4, and DQ5 for the ×8 chip.

In the right side region (RIGHT) of the chip, output of the first CRC encoding circuit CRC1R is supplied to the second encoding circuit CRC2R in the right side region and the second encoding circuit CRC2L in the left side region.

A CRC code bit output path GIOCRC of the second CRC encoding circuit CRC2R, similar to the common data output path GIO2, is connected to inputs of the output buffers FIFO

of: the output pins DQ2 and DQ3 in the ×4 configuration, and

of the output pins DQ2, DQ3, DQ4, and DQ5 in the ×8 configuration.

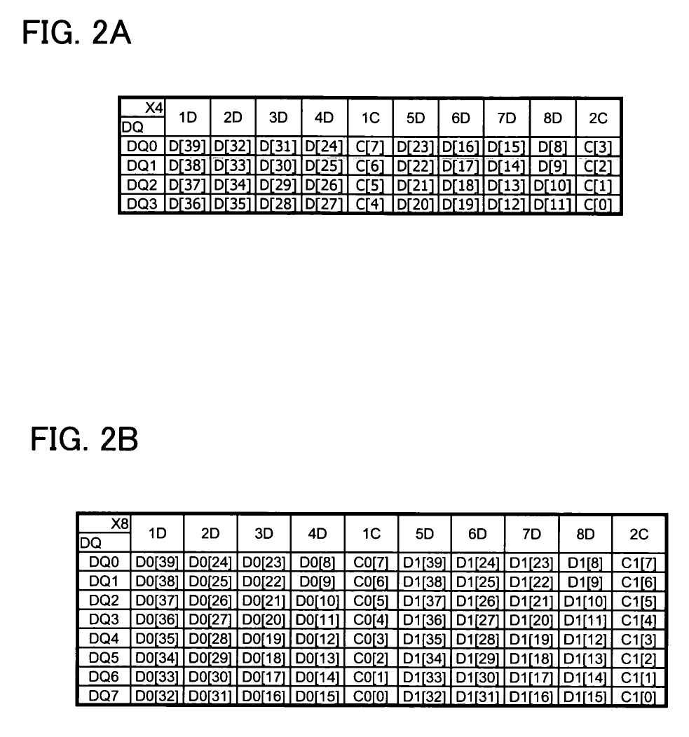

FIGS. 2A and 2B show relationships of data numbers of data groups, output pins, and data output order, for the two word configurations ×4 and ×8 implemented in the chip of FIGS. 1A and 1B. Here, the CRC encoding assumes a configuration in which 8-bit CRC code is added with respect to 32-bit data bits.

FIG. 2A shows, in case the word configuration is ×4, order of data externally output from the data output pins DQ0, DQ1, DQ2, and DQ3, and Output order of CRC bits.

In the present exemplary embodiment, with regard to output data groups of 32 bits data bits D[39] to D[8], and 8 bits of CRC bits C[7] to C[0], the data output order, as shown in FIG. 2A, for data numbers D[39], D[38], D[37], D[36], D[35], D[34], D[33], D[32], D[31], . . . , D[9], and D[8], in descending order, is as in IO pins DQ0, DQ1, DQ2, DQ3, DQ3, DQ2, DQ1, DQ0, DQ0, . . . , DQ1 and DQ0.

Among data bit output timing 1D, 2D, 3D, 4D, 5D, 6D, 7D, and 8D, for odd number output (1D, 3D, 5D, 7D), data numbers are in descending order with respect to the order DQ0, DQ1, DQ2, and DQ3, and for even number output (2D, 4D, 6D, 8D), data numbers are in descending order with respect to the order DQ3, DQ2, DQ1 and DQ0.

FIG. 2B shows, in case the word configuration is ×8, order of data externally output from the data output pins DQ0, DQ1, DQ2, DQ3, DQ4, DQ5, DQ6, and DQ7, and Output order of CRC bits.

In the present exemplary embodiment, the output data groups are two data bit groups D0[39]-D0[8], and D1[39]-D1[8] each being 32-bit, and two CRC bit groups C0[7]-C0[0] and C1[7]-C1[0] each being 8-bit.

Data output orders, similar to FIG. 2A previously described, for descending-order data D0[39], D0[38], D0[37], D0[36], D0[35], D0[34], D0[33], D0[32], D0[31], D0[30], D0[29], D0[28], D0[27], D0[26], D0[25], D0[24], D0[23], . . . , D0[9] and D0[8], and for descending-order data D1[39], D1[38], D1[37], D1[36], D1[35], D1[34], D1[33], D1[32], D1[31], D1[30], D1[29], D1[28], D1[27], D1[26], D1[25], D1[24], D1[23], . . . , D1[9] and D1[8], are as in IO pins DQ0, DQ1, DQ2, DQ3, DQ4, DQ5, DQ6, DQ7, DQ7, DQ6, DQ5, DQ4, DQ3, DQ2, DQ1, DQ0, DQ0 . . . DQ1, and DQ0

Among data output timing 1D, 2D, 3D and 4D, with regard to odd number output (1D, 3D, 5D, 7D), data numbers are in descending order, for the order DQ0, DQ1, DQ2, DQ3, DQ4, DQ5, DQ6, and DQ7, and with regard to even number output (2D, 4D, 6D, 8D), data numbers are in descending order, for the order DQ7, DQ6, DQ5, DQ4, DQ3, DQ2, DQ1, and DQ0.

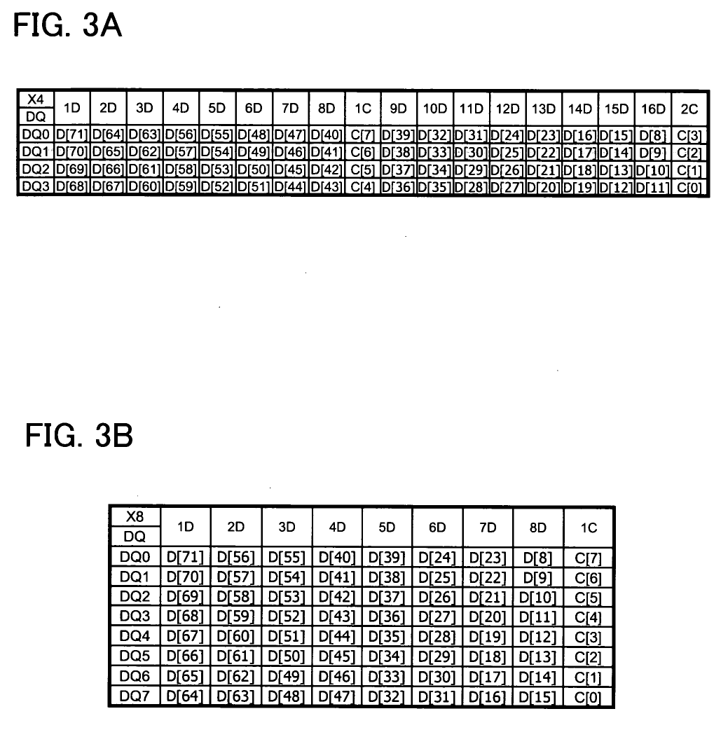

FIGS. 3A and 3B, similar to FIGS. 2A and 2B, show another example of relationships of data numbers of data groups, output pins, and data output order, for 2 word configurations ×4 and ×8, implemented in the chip of FIGS. 1A and 1B. Here, the CRC encoding assumes a configuration in which 8-bit CRC code is added with respect to 64-bit data bits.

FIG. 3A shows, in case the word configuration is ×4, order of data externally output from the data output pins DQ0, DQ1, DQ2, and DQ3, and output order of CRC bits.

In the present exemplary embodiment, with regard to output data groups, in case of 64 bits as far as data bits D[71] to D[8], and 8 bits of CRC bits C[7] to C[0], data output order, as shown in FIG. 3A, for data numbers D[71], D[70], D[69], D[68], D[67], D[66], D[65], D[64], D[63] . . . , D[9] and D[8], in descending order, is DQ0, DQ1, DQ2, DQ3, DQ3, DQ2, DQ1, DQ0, DQ0, . . . DQ1, and DQ0.

Among data bit output timing 1D, 2D, 3D, 4D, 5D, 6D, 7D, and 8D, for odd number output (1D, 3D, 5D, 7D), data numbers are in descending order with respect to the pin order DQ0, DQ1, DQ2 and DQ3, and for even number output (2D, 4D, 6D, 8D), data numbers are in descending order with respect to the pin order DQ3, DQ2, DQ1 and DQ0.

FIG. 3B shows, in case the word configuration is ×8, order of data externally output from the data output pins DQ0, DQ1, DQ2, DQ3, DQ4, DQ5, DQ6, and DQ7, and Output order of CRC bits.

In the present exemplary embodiment, output data groups are formed of 64-bit data bit groups D[71]-D[8], and 8-bit CRC bit groups C[7]-C[0].

Data output order, similar to FIG. 3A, for descending-order data D[71], D[70], D[69], D[68], D[67], D[66], D[65], D[64], D[63], D[62], D[61], D[60], D[59], D[58], D[57], D[56], D[55], . . . , D[9] and D[8], is as in the IO pin order DQ0, DQ1, DQ2, DQ3, DQ4, DQ5, DQ6, DQ7, DQ7, DQ6, DQ5, DQ4, DQ3, DQ2, DQ1, DQ0, DQ0, . . . DQ1 and DQ1.

Among data bit output timing 1D, 2D, 3D, 4D, for odd number output (1D, 3D, 5D, 7D), data numbers are in descending order with respect to the order DQ0, DQ1, DQ2, DQ3, DQ4, DQ5, DQ6, and DQ7, and for even number output (2D, 4D, 6D, 8D), data numbers are in descending order, with respect to the order DQ7, DQ6, DQ5, DQ4, DQ3, DQ2, DQ1 and DQ0.

Using

G(x)=x̂8+x̂2+x+1

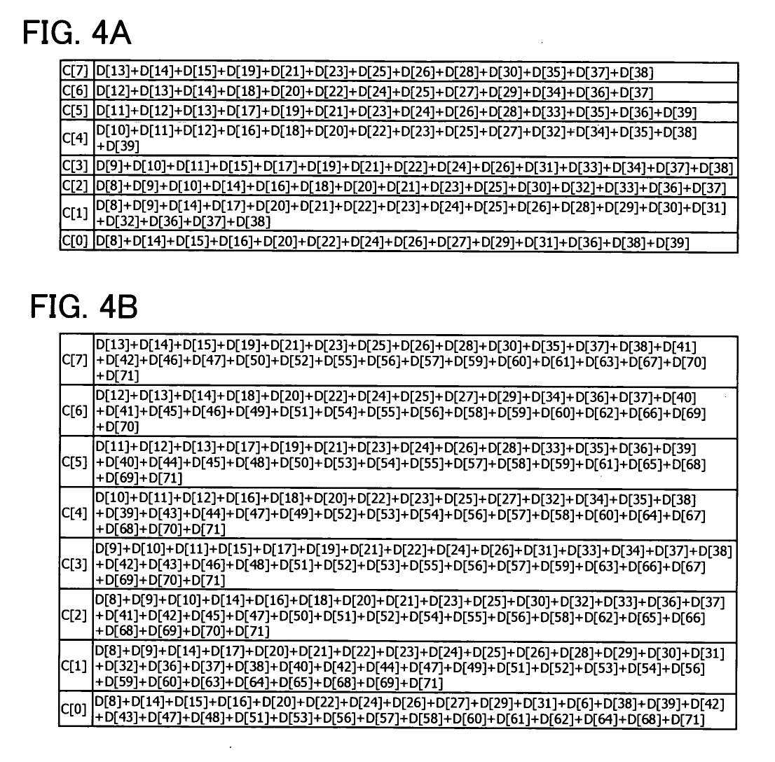

as a generator polynomial G(x) in CRC encoding, FIG. 4A shows relationships of data bits D[39]-D[8] and CRC bits C[7]-C[0].

### Using

G(x)=x̂8+x̂2+x+1

as a generator polynomial G(x) in CRC encoding in case output data groups are 64-bit, FIG. 4B shows relationships of data bits D[71]-D[8] and CRC bits C[7]-C[0].

As shown in FIGS. 4A and 4B, each CRC code bit is computed by exclusive OR operations (mod2 addition) for a plurality of data bits. Data bit combinations differ according to configuration of the generator polynomial. The generator polynomial is not limited to G(x)=x̂8+x̂2+x+1, used in the present exemplary embodiment, and a polynomial that implements CRC is adequate.

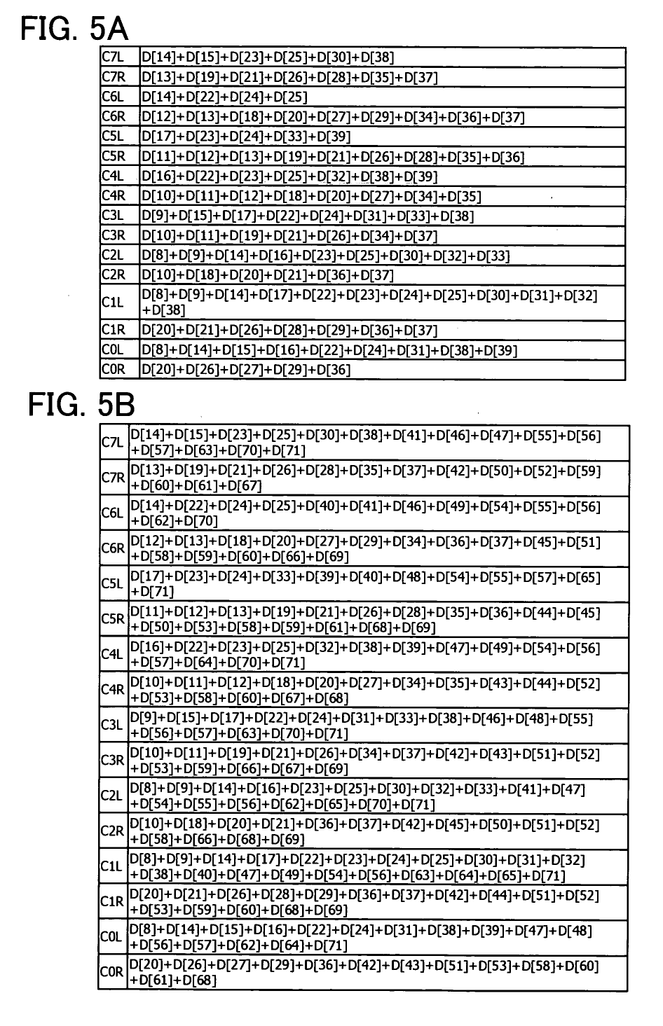

Among data bit groups necessary for generating each CRC bit shown in FIG. 4A, FIG. 5A shows CRC intermediate calculation results C7L, C6L, C5L, C4L, C3L, C2L, C1L, and C0L, computed by collecting only data in the left side region (LEFT) of the chip, and CRC intermediate calculation results C7R, C6R, C5R, C4R, C3R, C2R, C1R, and C0R, computed by data in the right side region (RIGHT) of the chip. In the same way, among data bit groups necessary for generating each CRC bit shown in FIG. 4B, FIG. 5B shows CRC intermediate calculation results C7L, C6L, C5L, C4L, C3L, C2L, C1L, and C0L, computed by collecting only data in the left side region (LEFT) of the chip, and CRC intermediate calculation results C7R, C6R, C5R, C4R, C3R, C2R, C1R, and C0R, computed by data in the right side region (RIGHT) of the chip.

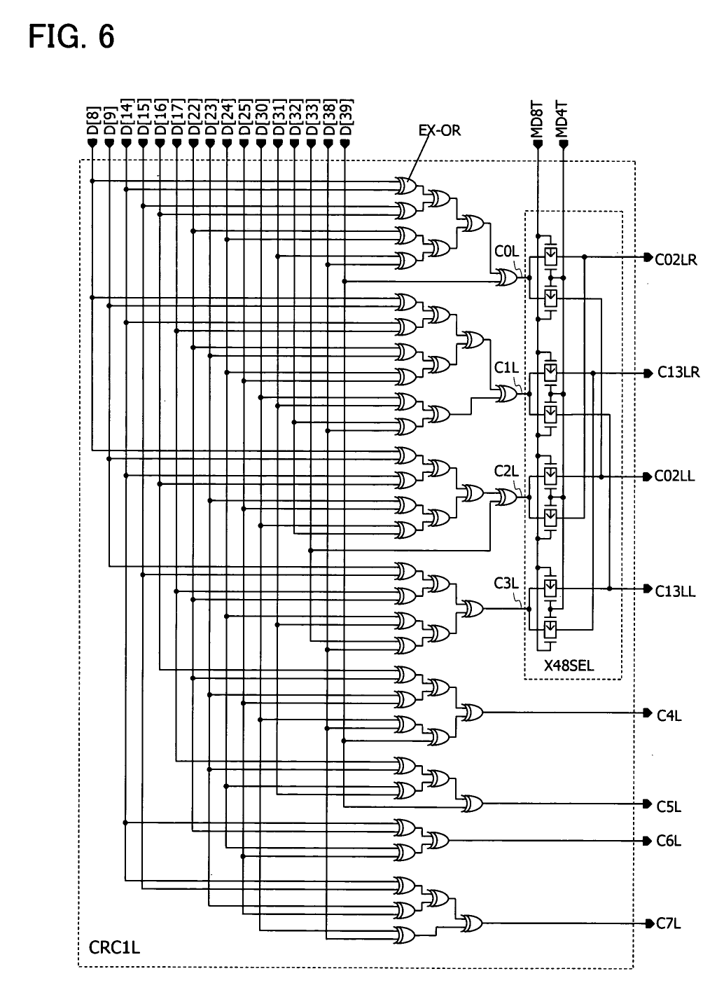

FIG. 6 shows one example of a configuration of the first CRC encoding circuit CRC1L that generates the CRC intermediate calculation results C7L, C6L, C5L, C4L, C3L, C2L, C1L, and C0L of FIG. 5A. This circuit is arranged in the left side region (LEFT) of the chip.

Each CRC intermediate calculation result is output as exclusive OR (EX-OR) operations for a plurality of data bits. In the present exemplary embodiment, two inputs exclusive OR circuits are provided at multiple stages. Multiple (more than 2) inputs type exclusive OR circuits may be used.

The circuit of FIG. 6, in addition, according to implemented word configuration, sends the generated CRC intermediate calculation results C7L, C6L, C5L, C4L, C3L, C2L, C1L, and C0L to either of the second CRC encoding circuits CRC2L and CRC2R on the chip left and right.

In the circuit of FIG. 6, among the CRC intermediate calculation results C7L, C6L, C5L, C4L, C3L, C2L, C1L, and C0L, the CRC intermediate calculation results C7L and C6L are supplied to the second CRC encoding circuit CRC2L on the left side of the chip, and the CRC intermediate calculation results C5L and C4L are supplied to the second CRC encoding circuit CRC2R on the right side of the chip.

The second CRC encoding circuit, which receives the CRC intermediate calculation results C0L, C1L, C2L, and C3L, differs to according to the implemented word configuration so that and an output destinations of C0L, C1L, C2L, and C3L are switched in an ×4, ×8 selection circuit X48SEL by an ×4 operation signal MD4T and an ×8 operation signal MD8T.

CRC intermediate calculation results C02LL and C13LL are supplied from the first CRC encoding circuit CRC1L on the left side region (LEFT) of the chip to the second CRC encoding circuit CRC2L on the left side region (LEFT) of the chip. CRC intermediate calculation results C2L and C3L are respectively output from C02LL and C13LL in ×4 operation, and CRC intermediate calculation results C0L and C1L are respectively output in ×8 operation.

In the same way, CRC intermediate calculation results C02LR and C13LR are supplied from the first CRC encoding circuit CRC1L on the left side region (LEFT) of the chip to the second CRC encoding circuit CRC2R on the right side region (RIGHT) of the chip. CRC intermediate calculation results C0L and C1L are respectively output from C02LR and C13LR in ×4 operation, and CRC intermediate calculation results C2L and C3L are respectively output in ×8 operation.

In the present exemplary embodiment, in this way, by switching transferred CRC intermediate calculation results, according to word configuration, it is possible to reduce the number of data buses crossing between left and right of the chip.

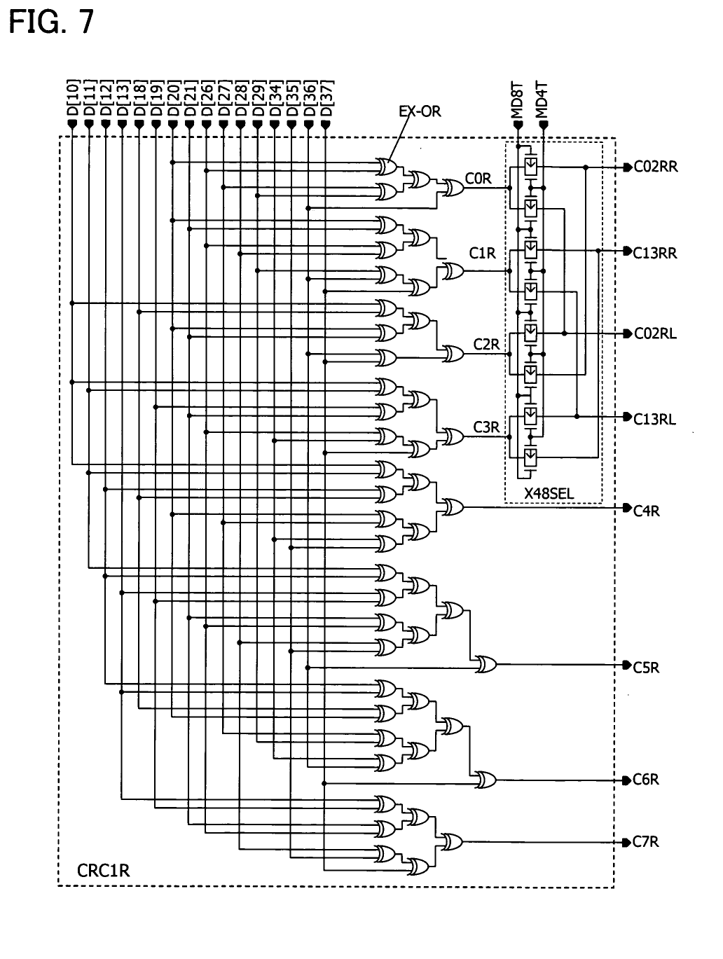

FIG. 7, similar to FIG. 6 on the left side region (LEFT) of the chip shows one example of a configuration of the first CRC encoding circuit CRC1R that generates the CRC intermediate calculation results C7R, C6R, C5R, C4R, C3R, C2R, C1R, and C0R of FIG. 5A, described previously. This circuit is arranged in the right side region (RIGHT) of the chip.

The circuit of FIG. 7, in accordance with the ×4 or the ×8 configuration, supplies the generated CRC intermediate calculation results C7R, C6R, C5R, C4R, C3R, C2R, C1R, and C0R to the second CRC encoding circuits CRC2L and CRC2R on the left and right regions of the chip.

In the circuit of FIG. 7, among the CRC intermediate calculation results C7R, C6R, C5R, C4R, C3R, C2R, C1R, and C0R, the CRC intermediate calculation results C7R and C6R are supplied to the second CRC encoding circuit CRC2L on the left side region (LEFT) of the chip, and the CRC intermediate calculation results C5R and C4R are supplied to the second CRC encoding circuit CRC2R on the right side of the chip.

With regard to the CRC intermediate calculation results C0R, C1R, C2R, and C3R transferred according to the implemented word configuration, the second CRC encoding circuit differs, and switching is performed, in the ×4, ×8 selection circuit X48SEL by the ×4 operation signal MD4T and the ×8 operation signal MD8T.

Here, intermediate calculation results C02RL and C13RL are supplied from the first CRC encoding circuit CRC1R on the right side region (RIGHT) of the chip to the second CRC encoding circuit CRC2L on the left side region (LEFT) of the chip. CRC intermediate calculation results C2R and C3R are output from C02RL and C13RL in ×4 operation, and CRC intermediate calculation results C0R and C1R are output in ×8 operation.

In the same way, CRC intermediate calculation results C02RR and C13RR are supplied from the first CRC encoding circuit CRC1R on the right side region (RIGHT) of the chip to the second CRC encoding circuit CRC2R on the right side region (RIGHT) of the chip. CRC intermediate calculation results C0R and C1R are output from C02RR and C13RR in ×4 operation, and CRC intermediate calculation results C2R and C3R are output in ×8 operation.

The circuit of FIG. 7, similar to cases of FIG. 6, by switching CRC intermediate calculation results that are transferred, according to word configuration, it is possible to reduce the number of data buses crossing between left and right of the chip.

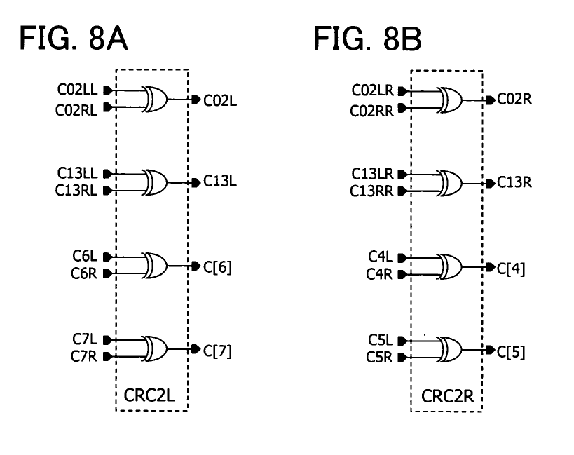

FIG. 8A and FIG. 8B respectively show examples of circuit configurations of the second CRC encoding circuit CRC2L and the second CRC encoding circuit CRC2R which receives the CRC intermediate calculation results output from the first CRC encoding circuits of FIG. 6 and FIG. 7.

Referring to FIG. 8A, the second CRC encoding circuit CRC2L is arranged on the left side region (LEFT) of the chip, and is supplied with CRC intermediate calculation results C7L, C6L, C02LL, and C13LL output from the first CRC encoding circuit CRC1L in the left side region (LEFT) of the chip, and CRC intermediate calculation results C7R, C6R, C02RL, and C13RL output from the second CRC encoding circuit CRC2L in the left side region (LEFT) of the chip. The second CRC encoding circuit CRC2L generates:

CRC bit C[7] from the CRC intermediate calculation results C7L and C7R;

CRC bit C[6] from the CRC intermediate calculation results C6L and C6R;

CRC bit C[2] in ×4 operation and CRC bit C[0] in ×8 operation, from the CRC intermediate calculation results C02LL and C02RL; and

CRC bit C[3] in ×4 operation and CRC bit C[1] in ×8 operation, from the CRC intermediate calculation results C13LL and C013RL.

In the same way, referring to FIG. 8B, the second CRC encoding circuit CRC2R is arranged in the right side region (RIGHT) of the chip and is supplied with CRC intermediate calculation results C5L, C4L, C02LR, and C13LR output from the first CRC encoding circuit CRC1L in the left side region (LEFT) of the chip, and CRC intermediate calculation results C5R, C4R, C02RR, and C13RR output from the second CRC encoding circuit CRC2L in the left side region (LEFT) of the chip. The second CRC encoding circuit CRC2R generates:

CRC bit C[5] from the CRC intermediate calculation results C5L and C5R;

CRC bit C[4] from the CRC intermediate calculation results C4L and C4R;

CRC bit C[0] in ×4 operation, and CRC bit C[2] in ×8 operation, from the CRC intermediate calculation results C02LR and C02RR; and

CRC bit C[1] in ×4 operation and CRC bit C[3] in ×8 operation, from the CRC intermediate calculation results C13LR and C13RR.

In this way, according to the present exemplary embodiment, by dividing CRC encoding to the first and second CRC encoding circuits, and furthermore by arranging separately on the left and right regions and switching intermediate calculation results to be transferred in ×4 and ×8 operations, with regard to the number of data buses crossing between the left side region (LEFT) of the chip and the right side region (RIGHT) of the chip, it is possible to have only 8 CRC intermediate calculation results C7R, C6R, C5L, C4L, C13LR, C13LR, C02RL, and C02RL, without the need to transfer all 32-bit data bits.

Furthermore, according to the present exemplary embodiment, by switching intermediate calculation results to be transferred in ×4 and ×8 operation, transmission lines can be shared and it is possible to reduce the number of data buses that form distribution lines.

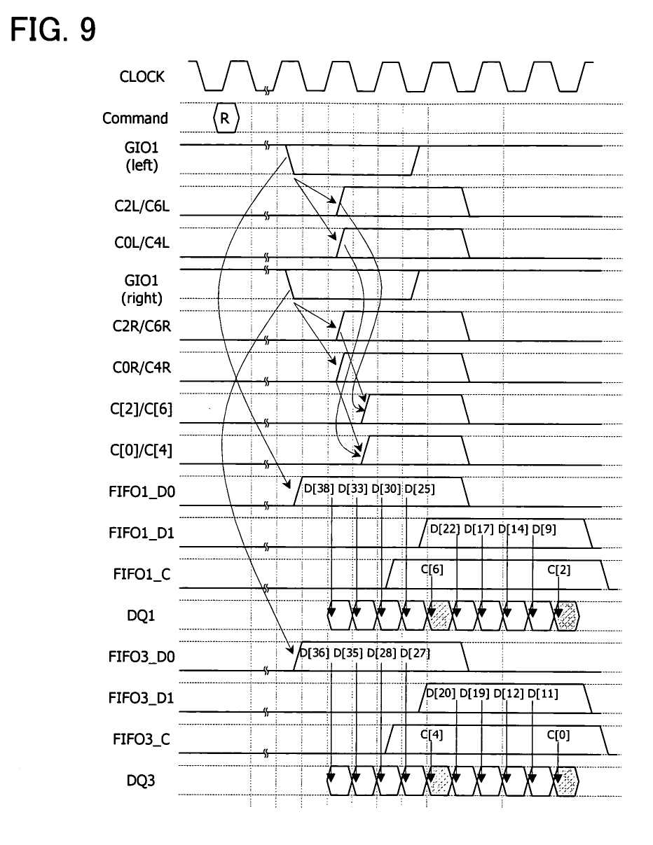

Next, a description is given concerning operation of the present exemplary embodiment for an ×4 chip configuration, using FIG. 9.

In accordance with an address and read command (R) sampled responsive to a clock edge, data corresponding to a selected address are supplied to the data output lines GIO1 on the left and right sides of the chip.

The data supplied to the data output lines GIO1 are delivered to the common data output lines GIO2 via multiplexers MUX8.

In the left side region (LEFT) of the chip, data groups output to the common data output line GIO2 are supplied to the output buffers FIFO of the output pins DQ0 and DQ1.

Here, an output buffer FIFO corresponding to DQ1 is described as an example.

Data D[38], D[33], D[30], and D[25], output the first 4 times (1D to 4D), are stored in the first output buffer FIFO1_D0, and data D[22], D[17], D[14], and D[9], output 4 times (8D to 8D) after a check bit, are stored in the second output buffer FIFO1_D1.

At the same time, data of the common data output line GIO2 are supplied to the first CRC encoding circuit CRC1L. The CRC intermediate calculation results C0L, C1L, C2L . . . , C7L are output from the first CRC encoding circuit CRC1L.

Among the CRC intermediate calculation results output from the first CRC encoding circuit CRC1L, C7L, C6L, C3L, and C2L are supplied to the second CRC encoding circuit CRC2L. At the same time, CRC intermediate calculation results C7R, C6R, C3R, and C2R output from the second encoding circuit CRC1R in the right side region (RIGHT) of the chip are supplied to the second CRC encoding circuit CRC2L. The CRC intermediate calculation results C3R and C2R are transferred via the CRC intermediate calculation result transmission lines C13RL and C02RL (FIG. 7).

The second CRC encoding circuit CRC2L receives the CRC intermediate calculation results and generates CRC bits C[7], C[6], C[3], and C[2].

The CRC bits C[6] and C[2] to be output from the output pin DQ1 are stored in a CRC bit output buffer FIFO1_C in an output buffer of the output pin DQ1.

CRC bits and data groups stored in the output buffers FIFO1_D0, FIFO1_D1, and FIFO1_C are output responsive to clock rising edge and falling edge.

Output order is as follows:

data bits D[38], D[33], D[30], and D[25] are output from the first output buffer FIFO1_D0;

after that, the CRC bit C[6] is output from the CRC output buffer FIFO1_C;

next, data bits D[22], D[17], D[14], and D[9] are output from the second output buffer FIFO1_D1; and

finally, the CRC bit C[2] is output from the CRC output buffer FIFO1_C.

With regard to operation of the right side region (RIGHT) of the chip, data groups output to the common data output line GIO2 are supplied to output buffers FIFO for the output pins DQ2 and DQ3. Here, an output buffer FIFO corresponding to DQ3 is described as an example.

Data D[36], D[35], D[28], and D[27] output the first 4 times (1D to 4D), are stored in the first output buffer FIFO3_D0, and data D[20], D[19], D[12], and D[11], output 4 times (5D to 8D) after a check bit, are stored in the second output buffer FIFO3_D1.

At the same time, data groups output to the common data output line GIO2 are supplied to the first CRC encoding circuit CRC1R.

The CRC intermediate calculation results C0R, C1R, C2RL . . . , C7R are output from the first CRC encoding circuit CRC1R.

Among the outputs of the CRC intermediate calculation results, C5R, C4R, C1R, and C0R are supplied to the second CRC encoding circuit CRC2R.

At the same time, CRC intermediate calculation results C5L, C4L, C1L, and C0L, from the second encoding circuit CRC1L in the left side region (LEFT) of the chip, are supplied to the first CRC encoding circuit CRC1R. The CRC intermediate calculation results C1L and C0L of the first CRC encoding circuit CRC1R are transferred via the CRC intermediate calculation result transmission lines C13LR and C02LR.

The second CRC encoding circuit CRC2R receives the CRC intermediate calculation results and generates CRC bits C[5], C[4], C[1], and C[0]. The CRC bits C[4] and C[0] to be output from the output pin DQ3 are stored in the CRC bit output buffer FIFO3_C, in the output buffer of the output pin DQ3.

CRC bits and data groups stored in the output buffers FIFO3_D0, FIFO3_D1, and FIFO3_C are output responsive to clock rising edge and falling edge.

Output order is as follows:

data bits D[36], D[35], D[28], and D[27] are output from the first output buffer FIFO3_D0;

after that, the CRC bit C[4] is output from the CRC output buffer FIFO3_C;

next, data bits D[20], D[19], D[12], and D[11] are output from the second output buffer FIFO3_D1; and

finally, the CRC bit C[0] is output from the CRC output buffer FIFO3_C.

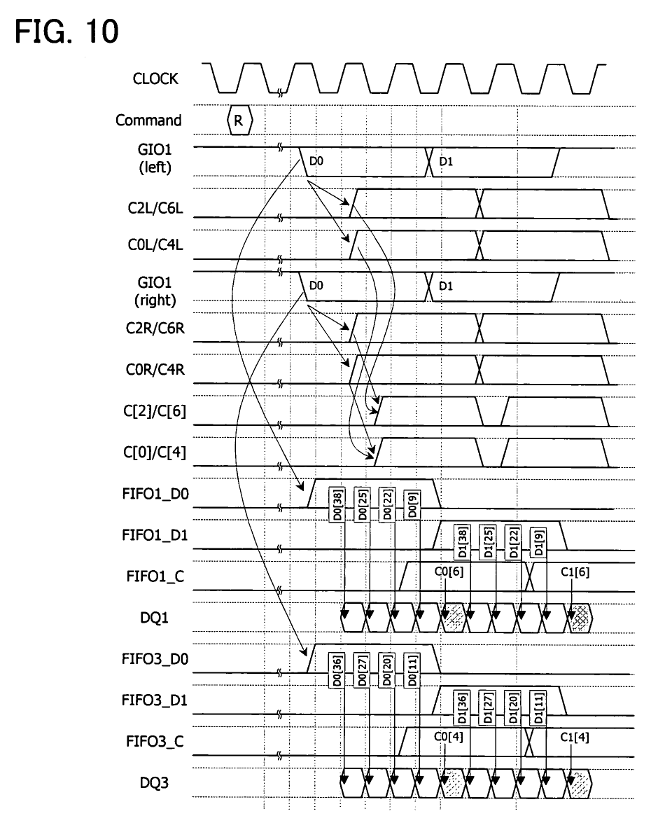

Next, operation with ×8 will be described, using FIG. 10.

In accordance with an address and read command captured responsive to a clock edge, data D0[39:8] corresponding to a selected address are supplied to the data output lines GIO1 on the left and right sides of the chip.

After the data D0[39:8] are output, subsequent data D1[39:8] are supplied to the data output lines GIO1.

The data D0 and D1 supplied to the data output lines GIO1 are delivered to the common data output lines GIO2 via the multiplexers MUX8.

In the left side region (LEFT) of the chip, data groups delivered to the common data output line GIO2 are supplied to the output buffers FIFO for the output pins DQ0, DQ1, DQ6, and DQ7.

An output buffer FIFO corresponding to DQ1 will now be described as an example.

Data D0[38], D0[25], D0[22], and D0[9] output from among a first data group the first 4 times (1D to 4D), are stored in the first output buffer FIFO1_D0, and data D1[38], D1[25], D1[22], and D1[9], output from among a second data group 4 times (5D to 8D) after a check bit, are stored in the second output buffer FIFO1_D1.

At the same time the output data D0 and D1 of the common data output line GIO2 are supplied to the first CRC encoding circuit CRC1L.

Here, first the CRC intermediate calculation results C0L, C1L, C2L . . . , C7L corresponding to the data group D0 are output.

Among the outputs of the CRC intermediate calculation results, C7L, C6L, C1L, and C0L are supplied to the second CRC encoding circuit CRC2L. At the same time, the CRC intermediate calculation results C7R, C6R, C1R, and C0R output from the second encoding circuit CRC1R in the right side region (RIGHT) of the chip, are supplied to the second CRC encoding circuit CRC2L. Here, the CRC intermediate calculation results C1R and C0R are transferred via the CRC intermediate calculation result transmission lines C13RL and C02RL (refer to FIG. 7).

The second CRC encoding circuit CRC2L receives the CRC intermediate calculation results and generates CRC bits C0[7], C0[6], C0[1], and C0[0] corresponding to the data group D0.

Among these, the CRC bit C0[6] to be output from the output pin DQ1 is stored in the CRC bit output buffer FIFO1_C, in the output buffer of the output pin DQ1.

After that, a similar operation is performed on the data group D1 supplied to the common data output path GIO2, and the CRC bit C1[6] corresponding to the data group D1 is stored in the CRC bit output buffer FIFO1_C of the output pin DQ1.

CRC bits and data groups stored in the output buffers FIFO1_D0, FIFO1_DL, and FIFO1_C are output responsive to clock rising edge and falling edge.

Output order is as follows:

data bits D0[38], D0[25], D0[22], and D0[9] are output from the first output buffer FIFO1_D0;

after that, the CRC bit C0[6] is output from the CRC output buffer FIFO1_C;

next, data bits D1[38], D1[25], D1[22], and D1[9] are output from the second output buffer FIFO1_D1; and

finally, the CRC bit C1[6] is output from the CRC output buffer FIFO1_C.

In the same way, on the right side of the chip section, data groups delivered to the common data output path GIO2 are supplied to the output buffers FIFO for the output pins DQ2, DQ3, DQ4, and DQ5. An output buffer FIFO corresponding to DQ3 will now be described as an example.

Data D0[36], D0[27], D0[20], and D0[11] output from among a first data group the first 4 times (1D to 4D), are stored in the first output buffer FIFO3_D0, and data D1[36], D1[27], D1[20], and D1[11], output from among a second data group 4 times (5D to 8D) after a check bit, are stored in the second output buffer FIFO3_D1.

At the same time the output data D0 and D1 of the common data output line are supplied to the first CRC encoding circuit CRC1R.

Here, first the CRC intermediate calculation results C0R, C1R, C2R . . . , C7R corresponding to the data group D0 are output. Among the outputs of the CRC intermediate calculation results, C5R, C4R, C3R, and C2R are supplied to the second CRC encoding circuit CRC2R.

At the same time, CRC intermediate calculation results C5L, C4L, C3L, and C2L from the second encoding circuit CRC1L in the left side region (LEFT) of the chip, are supplied to the second CRC encoding circuit CRC2R.

The CRC intermediate calculation results C3L and C2L are transferred via the CRC intermediate calculation result transmission lines C13LR and C02LR. The second CRC encoding circuit CRC2R receives the CRC intermediate calculation results and generates CRC bits C0[5], C0[4], C0[3], and C0[2] corresponding to the data group D0.

Among these, the CRC bit C0[4] to be output from the output pin DQ3 is stored in the CRC bit output buffer FIFO3_C in the output buffers of the output pin DQ3.

And that, a similar operation is performed on the data group D1 supplied to the common data output path GIO2, and the CRC bit C1[4] corresponding to the data group D1 is stored in the CRC bit output buffer FIFO3_C of the output pin DQ3.

CRC bits and data groups stored in the output buffers FIFO3_D0, FIFO3_D1, and FIFO3_C are output responsive to clock rising edge and falling edge.

Output order is as follows:

data bits D0[36], D0[27], D0[20], and D0[11] are output from the first output buffer FIFO3_D0;
after that, the CRC bit C0[4] is output from the CRC output buffer FIFO3_C;

next, data bits D1[36], D1[27], D1[20], and D[11] are output from the second output buffer FIFO3_D1; and

finally, the CRC bit C1[4] is output from the CRC output buffer FIFO3_C.

Effects and features of the present exemplary embodiment will now be described.

In a chip handling both ×4 and ×8 configurations, in correspondence with data output order in which data output from DQ0 and DQ1, or DQ2 and DQ3, in the ×4 configuration, are output from DQ0, DQ1, DQ6, and DQ7, or DQ2, DQ3, DQ4, and DQ5, in the ×8 configuration, data addresses inside the chip are made the same in the ×4 and ×8 configurations. Further, with the arrangement in which DQ6 and DQ7 are provided adjacent to DQ0 and DQ1, and DQ4 and DQ5 are provided adjacent to DQ2 and DQ3, it is possible to use common CRC encoding circuits, for the ×4 and ×8 configurations, thereby reducing chip area and reducing the number of data buses crossing between left and right of the chip. By switching data supplied to CRC intermediate calculation result transfer paths that cross between the CRC encoding circuits according to the word configuration, it is possible to reduce the number of wires.

Conversely, in a chip handling ×4 and ×8 configurations, in which DQ6 and DQ7 are arranged adjacent to output pins DQ0 and DQ1, and DQ4 and DQ5 are arranged adjacent to DQ2 and DQ3, by setting the data output order in such an order in which data from DQ0 and DQ1, or DQ2 and DQ3, in the ×4 configuration are output from DQ0, DQ1, DQ6, and DQ7, or DQ2, DQ3, DQ4, and DQ5, in the ×8 configuration, it is possible to use common CRC encoding circuits, thereby reducing chip area.

### Second Exemplary Embodiment

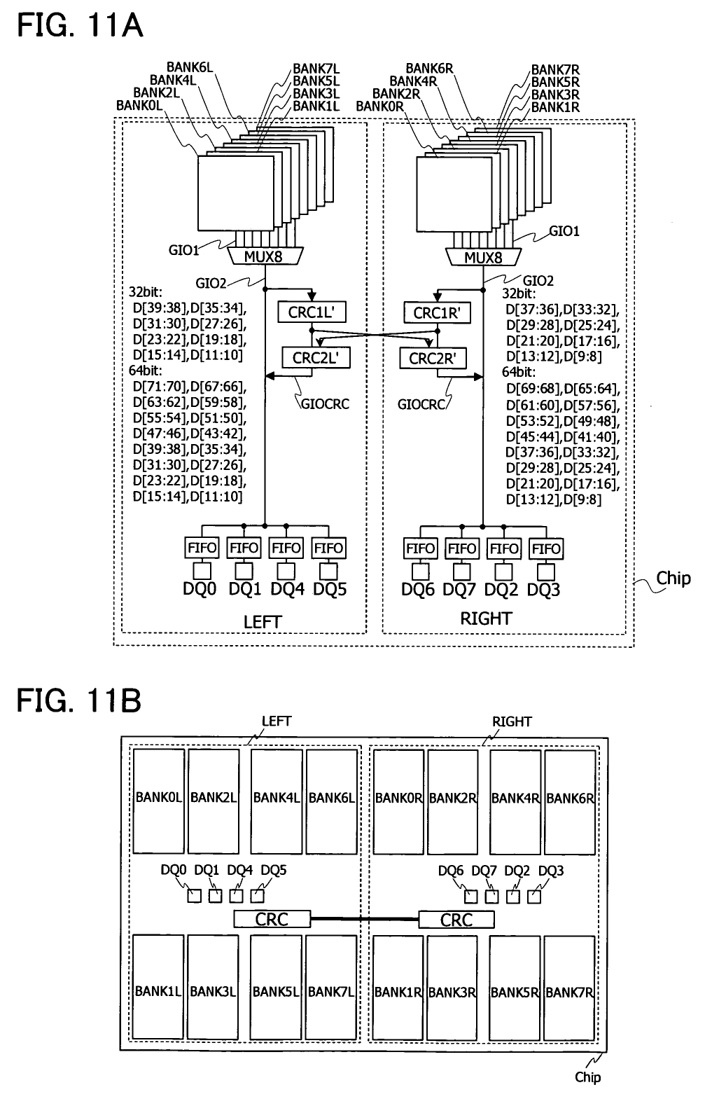

FIG. 11A and FIG. 11B show block diagrams indicating a data bus configuration of a DRAM and a physical chip image, being a second exemplary embodiment of the present invention.

In the present exemplary embodiment, in a plurality of word configurations, CRC encoding circuits are shared, chip area is reduced, and the number of data buses inside a chip is reduced by arrangement of output pins.

The present exemplary embodiment differs from the first exemplary embodiment and is distinguished in order of output data has a sequence in an order of output pins DQ0, DQ1, DQ2, DQ3, DQ4, DQ5, DQ6, and DQ7.

For the same chip, FIG. 11A is a block diagram of a chip in which, at one data output timing, an ×4 configuration outputting 4 items of data and an ×8 configuration outputting 8 items of data are implemented on the same chip.

The chip includes a left side region LEFT and a right side region RIGHT.

In the left side region (LEFT), DQ0, DQ1, DQ4, and DQ5 are arranged as output pins, and in case of an ×4 configuration, output pins DQ0 and DQ1 are used, and output pins DQ4 and DQ5 are not used in data output.

For the ×8 configuration, all of the output pins DQ0, DQ1, DQ4, and DQ5 are used.

Output pins DQ4 and DQ5 are arranged adjacent to output pins DQ0 and DQ1. This arrangement differs from the first exemplary embodiment.

This lies in the fact that in data output order, described later, output data of the output pins DQ0 and DQ1 in the ×4 configuration are output from DQ0, DQ1, DQ4, and DQ5 in the ×8 configuration. With this type of configuration, it is possible to share the CRC encoding circuits among a plurality of word configurations, and a data bus crossing between left and right of the chip become necessitated (may be unnecessary).

Half of a memory bank region of each memory bank, BANK0L, BANK1L, BANK2L, BANK3L, BANK4L, BANK5L, BANK6L, and BANK7L is arranged in the left side region (LEFT) of the chip.

A bank data output path GIO1 is connected to each memory bank, and is connected to a multiplexer MUX8. Data output to the data output buses GIO1 are, in case of a 32 bit read chip, data groups D[39:38], D[35:34], D[31:30], D[27:26], D[23:22], D[19:18], D[15:14], and D[11:10], and in case of a 64 bit read chip, data groups D[71:70], D[67:66], D[63:62], D[59:58], D[55:54], D[51:50], D[47:46], D[43:42], D[39:38], D[35:34], D[31:30], D[27:26], D[23:22], D[19:18], D[15:14], and D[11:10].

Here, since the same CRC encoding circuits are used for the ×4 configuration and the ×8 configuration, data numbers are the same for the ×4 configuration and the ×8 configuration, similar to the first exemplary embodiment.

The multiplexer MUX8, according to a read command and an input address, connects the bank data output path GIO1 from one memory bank and a common data output path GIO2.

The common data output path GIO2 inputs to a first CRC encoding circuit CRC1L.

At the same time, input is provided to output buffers FIFO of output pins DQ0 and DQ1 for the ×4 configuration, and output pins DQ0, DQ1, DQ4 and DQ5 for the ×8 configuration.

Output of the first CRC encoding circuit CRC1L is supplied to a second encoding circuit CRC2L inside the left side region (LEFT) and a second encoding circuit CRC2R inside the right side region (RIGHT).

A CRC code bit output path GIOCRC of the second CRC encoding circuit CRC2L, similar to the common data output path GIO2, is connected to input of output buffers FIFO of output pins DQ0 and DQ1 in the ×4 configuration, and output pins DQ0, DQ1, DQ4 and DQ5 in the ×8 configuration.

In the same way, DQ2, DQ3, DQ6, and DQ7 are arranged as output pins in the right side region (RIGHT) of the chip.

In the ×4 configuration the output pins DQ2 and DQ3 are used, and the output pins DQ6 and DQ7 are not used as data output.

In the ×8 configuration, all of the output pins DQ2, DQ3, DQ6, and DQ7 are used. Output pins DQ6 and DQ7 are arranged adjacent to output pins DQ2 and DQ3. This differs from the first exemplary embodiment. Similar to the left side region (LEFT) of the chip, in data output order, described later, since output data of the output pins DQ2 and DQ3 in the ×4 configuration are output from DQ2, DQ3, DQ6, and DQ7 in the ×8 configuration. With this type of configuration, it is possible to share the CRC encoding circuits among a plurality of word configurations, and a data bus crossing between left and right of the chip becomes necessitated (may be unnecessary).

Half of a memory bank region of each memory bank, BANK0R, BANK1R, BANK2R, BANK3R, BANK4R, BANK5R, BANK6R, and BANK7R is arranged in the right side region (RIGHT) of the chip.

A bank data output path GIO1 is connected to each memory bank, and is connected to a multiplexer MUX8. Data delivered to the data output bus GIO1 are, in case of a 32-bit read chip, D[37:36], D[33:32], D[29:28], D[25:24], D[21:20], D[17:16], D[13:12], and D[9:8], and in case of a 64-bit read chip, D[69:68], D[65:64], D[61:60], D[57:56], D[53:52], D[49:48], D[45:44], D[41:40], D[37:36], D[33:32], D[29:28], D[25:24], D[21:20], D[17:16], D[13:12], and D[9:8].

Similar to the abovementioned left side region of the chip, since the same CRC encoding circuits are used for the ×4 configuration and the ×8 configuration, data numbers are the same for the ×4 configuration and the ×8 configuration.

The multiplexer MUX8, in accordance with read command and input address, connects the bank data output path GIO1 from one memory bank and a common data output path GIO2.

The common data output path GIO2 is supplied to a first CRC encoding circuit CRC1R.

At the same time, input is provided to output buffers FIFO of the output pins DQ2 and DQ3, in case of the ×4 configuration, and DQ2, DQ3, DQ6, and DQ7 in case of the ×8 configuration.

Output of the first CRC encoding circuit CRC1R is supplied to the second encoding circuit CRC2R inside the right side region and the second encoding circuit CRC2L inside the left side region.

A CRC code bit output path GIOCRC of the second CRC encoding circuit CRC2R, similar to the abovementioned common data output path GIO2, is connected to input of the output buffers FIFO of the output pins DQ2 and DQ3, in case of the ×4 configuration, and DQ2, DQ3, DQ6, and DQ7 in case of the ×8 configuration.

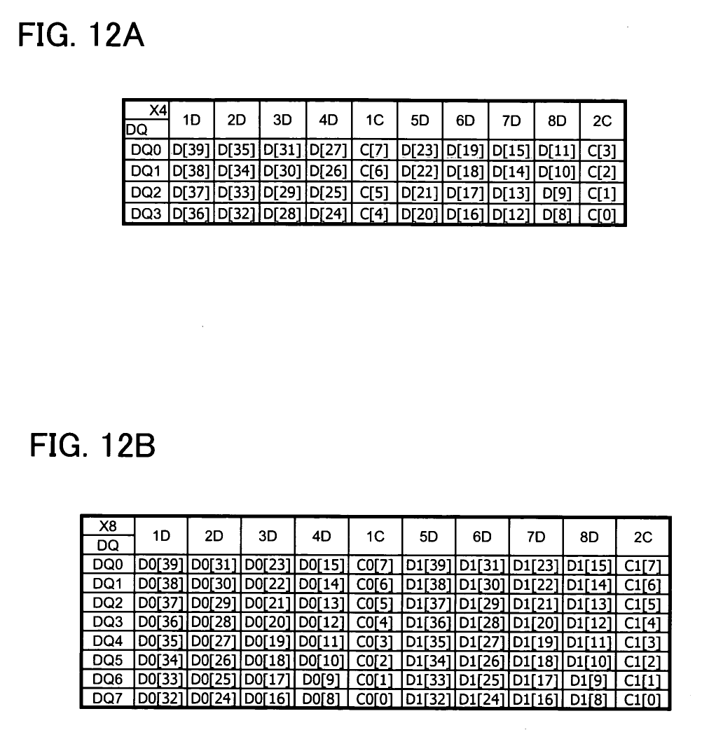

FIGS. 12A and 12B show relationships of data numbers of data groups, output pins, and data output order, for the two word configurations ×4 and ×8 implemented in the chip of FIGS. 11A and 11B. Here, the CRC encoding assumes a configuration in which 8-bit CRC code is added with respect to 32-bit data bits.

FIG. 12A shows, in case of the word configuration being ×4, order of data externally output from the data output pins DQ0, DQ1, DQ2, and DQ3, and Output order of CRC bits.

The present exemplary embodiment is distinguished in that, with regard to output data groups, in case of 32 bits as far as data bits D[39] to D[8], and 8 bits of CRC bits C[7] to C[0], data output order, as shown in the figure, for data numbers D[39], D[38], D[37], D[36], D[35], D[34], D[33], D[32], . . . , D[9] and D[8], in descending order, is as in output pins DQ0, DQ1, DQ2, DQ3, DQ0, DQ1, DQ2, DQ3 . . . , DQ2 and DQ3. With any of data bit output timing 1D, 2D, 3D, 4D, 5D, 6D, 7D, 8D, data numbers are in descending order with respect to the order of data pins DQ0, DQ1, DQ2, and DQ3.

FIG. 12B shows, in case of the word configuration being ×8, order of data externally output from the data output pins DQ0, DQ1, DQ2, DQ3, DQ4, DQ5, DQ6, and DQ7, and output order of CRC bits.

In the present exemplary embodiment, the output data groups are two data bit groups D0[39]-D0[8], and D1[39]-D1[8] each being 32-bit, and two CRC bit groups C0[7]-C0[0] and C1[7]-C1[0] each being 8-bit.

Data output order, similar to FIG. 12A as previously described, for descending-order data D0[39], D0[38], D0[37], D0[36], D0[35], D0[34], D0[33], D0[32], . . . , D0[9], D0[8], and D1[39], D1[38], D1[37], D1[36], D1[35], D1[34], D1[33], D1[32], . . . , D1[9] and D1[8], is DQ0, DQ1, DQ2, DQ3, DQ4, DQ5, DQ6, DQ7, DQ0, DQ1, DQ2, DQ3, DQ4, DQ5, DQ6, DQ7, . . . DQ6 and DQ7.

For any data output timing 1D, 2D, 3D and 4D, data numbers are in descending order with respect to the order of data pins DQ0, DQ1, DQ2, DQ3, DQ4, DQ5, DQ6, and DQ7.

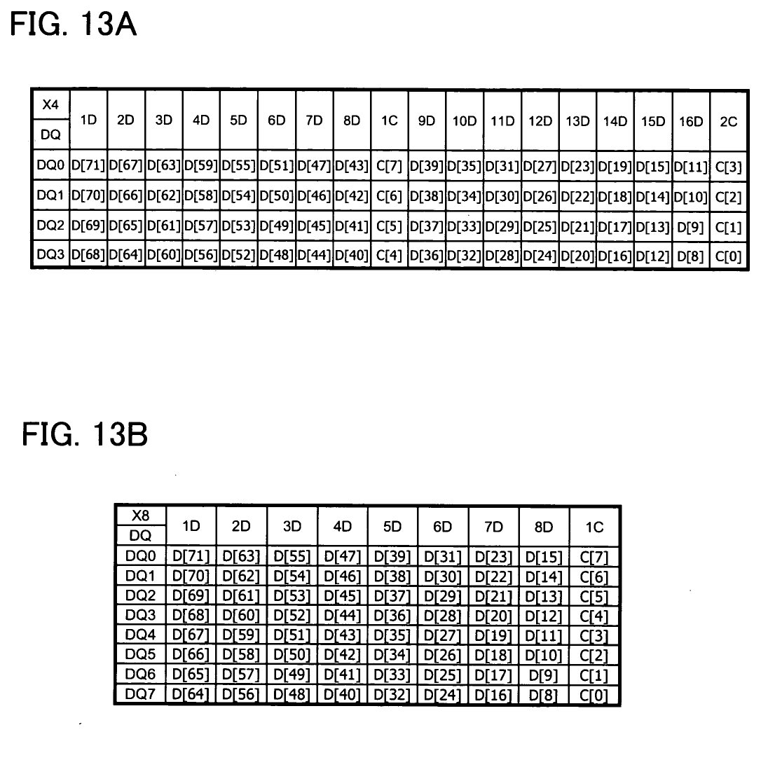

FIGS. 13A and 13B, similar to FIGS. 12A and 12B, show another example of relationships of data numbers of data groups, output pins, and data output order, for two word configurations ×4 and ×8 implemented in the chip of FIGS. 11A and 11B.

The CRC encoding assumes a configuration in which 8-bit CRC code is added with respect to 64-bit data bits.

FIG. 13A shows, in case the word configuration is ×4, order of data externally output from the data output pins DQ0, DQ1, DQ2, and DQ3, and Output order of CRC bits.

In the present exemplary embodiment, with regard to output data groups, in case of 64 bits as far as data bits D[71] to D[8], and 8 bits of CRC bits C[7] to C[0], data output order, as shown in the figure, for data numbers D[71], D[70], D[69], D[67], D[66], D[65], D[64], . . . , D[9], D[8], in descending order, is as in output pins DQ0, DQ1, DQ2, DQ3, DQ0, DQ1, DQ2, DQ3 . . . , DQ2 and DQ3. With any data bit output timing 1D, 2D, 3D, 4D, 5D, 6D, 7D, and 8D, data numbers are in descending order with respect to the order of data pins DQ0, DQ1, DQ2, and DQ3.

FIG. 13B shows, in case the word configuration is ×8, order of data externally output from the data output pins DQ0, DQ1, DQ2, DQ3, DQ4, DQ5, DQ6, and DQ7, and Output order of CRC bits.

In the present exemplary embodiment, output data groups are formed of a 64-bit data bit group D[71] to D[8], and 8-bit CRC bit group C[7] to C[0].

Data output order, similar to FIG. 13A as described previously, for descending-order data D[71], D[70], D[69], D[68], D[67], D[66], D[65], D[64], D[63], D[62], D[61], D[60], D[59], D[58], D[57], D[56], . . . , D[9], D[8], is as in output pins DQ0, DQ1, DQ2, DQ3, DQ4, DQ5, DQ6, DQ7, DQ0, DQ1, DQ2, DQ3, DQ4, DQ5, DQ6, DQ7, . . . , DQ6 and DQ7. With any of data output timing 1D, 2D, 3D and 4D, data numbers are in descending order with respect to the order of data pins DQ0, DQ1, DQ2, DQ3, DQ4, DQ5, DQ6, and DQ7.

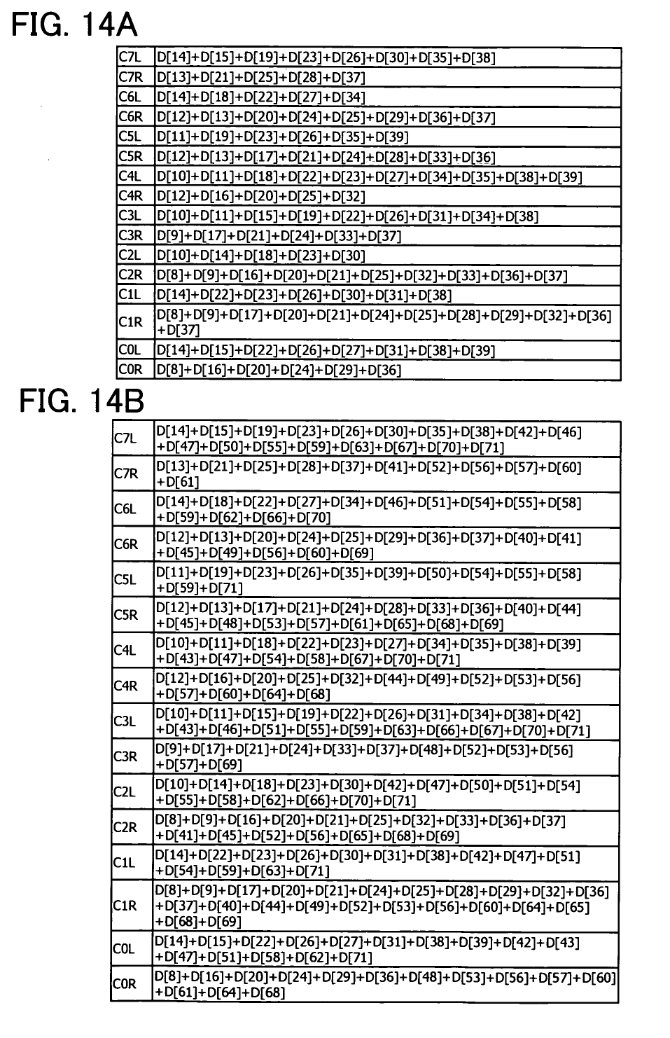

Among a data bit group necessary for generating each CRC bit shown in FIG. 4A described above, FIG. 14A shows CRC intermediate calculation results C7L, C6L, C5L, C4L, C3L, C2L, C1L, and C0L, computed by collecting only data in the left side region (LEFT) of the chip, and CRC intermediate calculation results C7R, C6R, C5R, C4R, C3R, C2R, C1R, and C0R, computed by data in the right side region (RIGHT) of the chip. Among a data bit group necessary for generating each CRC bit shown in FIG. 4B described above, FIG. 14B shows CRC intermediate calculation results C7L, C6L, C5L, C4L, C3L, C2L, C1L, and C0L, computed by collecting only data in the left side region (LEFT) of the chip, and CRC intermediate calculation results C7R, C6R, C5R, C4R, C3R, C2R, C1R, and C0R, computed by data in the right side region (RIGHT) of the chip.

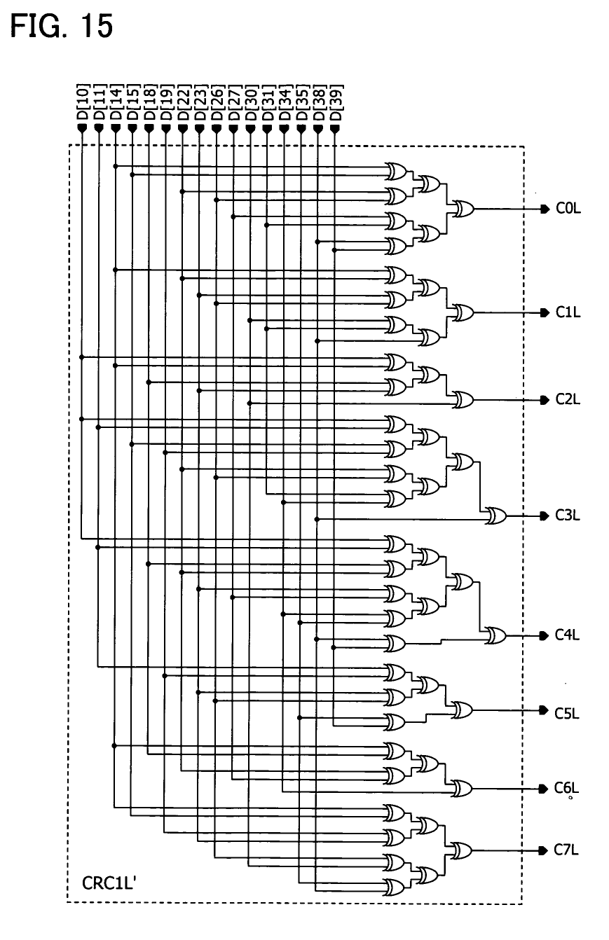

FIG. 15 shows one example of a configuration of a first CRC encoding circuit CRC1L′ that generates the CRC intermediate calculation results C7L, C6L, C5L, C4L, C3L, C2L, C1L, and C0L of FIG. 14A. This circuit is arranged in the left side region (LEFT) of the chip.

Each CRC intermediate calculation result is output by exclusive OR (EX-OR) operations for a plurality of data bits. In the present exemplary embodiment, two inputs exclusive-OR circuits are used at multiple stages. Multiple (more than 2) inputs type exclusive OR circuits may be used.

The circuit of FIG. 15, in addition, according to the ×4 configuration or the ×8 configuration, delivers the generated CRC intermediate calculation results C7L, C6L, C5L, C4L, C3L, C2L, C1L, and C0L to either of second CRC encoding circuits CRC2L′ and CRC2R′ on the left and right side regions of the chip.

Among the CRC intermediate calculation results C7L, C6L, C5L, C4L, C3L, C2L, C1L, and C0L from the first CRC encoding circuit CRC1L′ of FIG. 15, the CRC intermediate calculation results C7L, C6L, C3L, and C2L are supplied to the second CRC encoding circuit CRC2L′ on the left side region (LEFT) of the chip, and the CRC intermediate calculation results C5L, C4L, C1L, and C0L are supplied to the second CRC encoding circuit CRC2R′ on the right side region (RIGHT) of the chip.

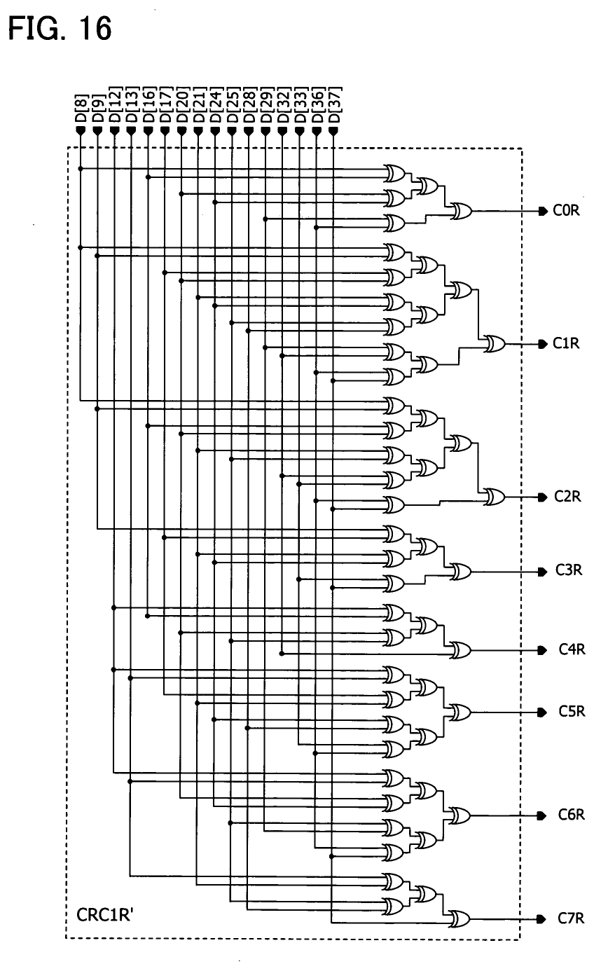

Similar to FIG. 15 with regard to the left side of the chip, FIG. 16 shows one example of a configuration of a first CRC encoding circuit CRC1R′ that generates the CRC intermediate calculation results C7R, C6R, C5R, C4R, C3R, C2R, C1R, and C0R of FIG. 14A. This circuit is arranged in the right side region (RIGHT) of the chip.

The circuit of FIG. 16, in addition, according to the ×4 configuration or the ×8 configuration, delivers the generated CRC intermediate calculation results C7R, C6R, C5R, C4R, C3R, C2R, C1R, and C0R to the second CRC encoding circuits CRC2L′ and CRC2R′ on the left and right side regions of the chip.

Among the CRC intermediate calculation results C7R, C6R, C5R, C4R, C3R, C2R, C1R, and C0R from the first CRC encoding circuit CRC1R′ of FIG. 16, the CRC intermediate calculation results C7R, C6R, C3R, and C2R are supplied to the second CRC encoding circuit CRC2L′ on the left side region (LEFT) of the chip, and the CRC intermediate calculation results C5R, C4R, C1R, and C0R are supplied to the second CRC encoding circuit CRC2R′ on the right side region (RIGHT) of the chip.

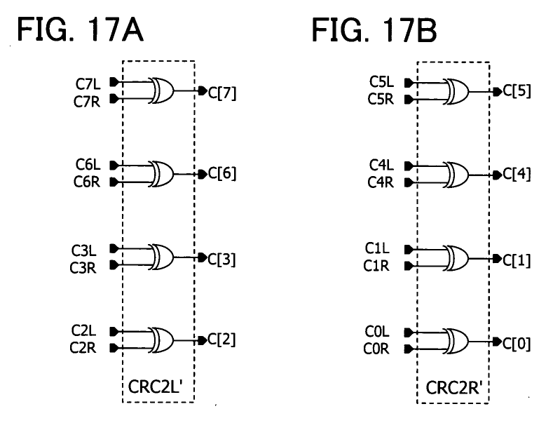

FIG. 17A and FIG. 17B respectively show an example of a circuit configuration of the second CRC encoding circuit CRC2L′ and the second CRC encoding circuit CRC2R′ which receives the CRC intermediate calculation results output from the first CRC encoding circuits of FIG. 15 and FIG. 16.

The second CRC encoding circuit CRC2L′ is arranged on the left side region (LEFT) of the chip, and is supplied with CRC intermediate calculation results C7L, C6L, C3L, and C2L output from the first CRC encoding circuit CRC1L′ in the left side region (LEFT) of the chip, and CRC intermediate calculation results C7R, C6R, C3R, and C2R output from the first CRC encoding circuit CRC2L′ in the right side region (RIGHT) of the chip. The second CRC encoding circuit CRC2L′ generates:

CRC bit C[7] from the CRC intermediate calculation results C7L and C7R;

CRC bit C[6] from the CRC intermediate calculation results C6L and C6R;

CRC bit C[3] from the CRC intermediate calculation results C3L and C3R; and

CRC bit C[2] from the CRC intermediate calculation results C2L and C2R.

In the same way, the second CRC encoding circuit CRC2R′ is arranged in the right side region (RIGHT) of the chip, and is supplied with CRC intermediate calculation results C5L, C4L, C1L, and C0L output from the first CRC encoding circuit CRC1L′ in the left side region (LEFT) of the chip, and CRC intermediate calculation results C5R, C4R, C1R, and C0R output from the first CRC encoding circuit CRC1R′ in the right side region (RIGHT) of the chip. The second CRC encoding circuit CRC2R′ generates:

CRC bit C[5] from the CRC intermediate calculation results C5L and C5R;

CRC bit C[4] from the CRC intermediate calculation results C4L and C4R;

CRC bit C[1] from the CRC intermediate calculation results C1L and C1R; and

CRC bit C[0] from the CRC intermediate calculation results C0L and C0R.

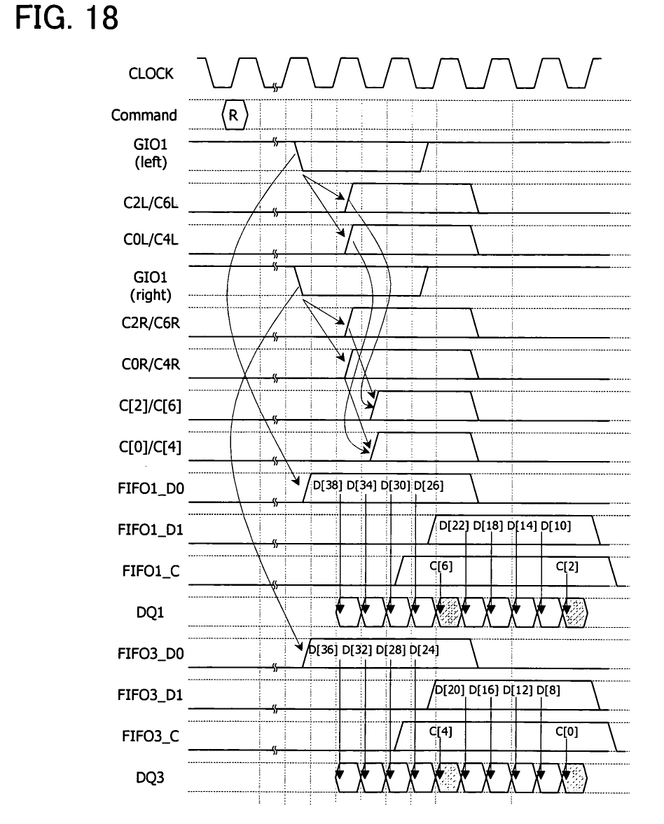

Next, a description is given concerning operation of the present exemplary embodiment for an ×4 configuration, using FIG. 18.

According to an address and a read command sampled responsive to a clock edge, data corresponding to a selected address are supplied to the data output lines GIO1 on the left and right sides of the chip.

The data supplied to the data output lines GIO1 are delivered to the common data output lines GIO2 via the multiplexers MUX8.

In the left side region (LEFT) of the chip, data groups delivered to the common data output line GIO2 are supplied to the output buffers FIFO for the output pins DQ0 and DQ1.

An output buffer FIFO corresponding to DQ1 will be described as an example.

Data D[38], D[34], D[30], and D[26] output the first 4 times (1D to 4D), are stored in the first output buffer FIFO1_D0, data D[22], D[18], D[14], and D[10], output 4 times (5D to 8D) after a check bit, are stored in the second output buffer FIFO1_D1.

At the same time, the data groups delivered to the common data output lines GIO2 are supplied to the first CRC encoding circuit CRC1L′. The CRC intermediate calculation results C0L, C1L, C2L . . . , C7L are output from the first CRC encoding circuit CRC1L′.

Among the CRC intermediate output results output from the first CRC encoding circuit CRC1L′, C7L, C6L, C3L, and C2L are supplied to the second CRC encoding circuit CRC2L′.

At the same time, the CRC intermediate calculation results C7R, C6R, C3R, and C2R from the second encoding circuit CRC1R′ in the right side region (RIGHT) of the chip, are supplied to the second CRC encoding circuit CRC2L′.

The second CRC encoding circuit CRC2L′ receives the CRC intermediate calculation results and generates CRC bits C[7], C[6], C[3], and C[2]. Among these, the CRC bits C[6] and C[2] to be output from the output pin DQ1 are stored in the CRC bit output buffer FIFO1_C, in the output buffer of the output pin DQ1.

CRC bits and data groups stored in the output buffers FIFO1_D0, FIFO1_D1, and FIFO1_C are output responsive to clock rising edge and falling edge.

Output order is as follows:

data bits D[38], D[34], D[30], and D[26] are output from the first output buffer FIFO1_D0;

after that, the CRC bit C[6] is output from the CRC output buffer FIFO1_C;

next, data bits D[22], D[18], D[14], and D[10] are output from the second output buffer FIFO1_D1; and

finally, the CRC bit C[2] is output from the CRC output buffer FIFO1_C.

With regard to operation of the right side region (RIGHT) of the chip, data groups delivered to the common data output line GIO2 are supplied to the output buffers FIFO for the output pins DQ2 and DQ3. An output buffer FIFO corresponding to DQ3 will be described as an example.

Data D[36], D[32], D[28], and D[24] output the first 4 times (1D to 4D), are stored in the first output buffer FIFO3_D0, and data D[20], D[16], D[12], and D[8], output 4 times (8D to 8D) after a check bit, are stored in the second output buffer FIFO3_D1.

At the same time, data groups delivered to the common data output lines GIO2 are supplied to the first CRC encoding circuit CRC1R′.

The CRC intermediate calculation results C0R, C1R, C2RL . . . , and C7R are output from the first CRC encoding circuit CRC1R. Among the CRC intermediate calculation results output from the first CRC encoding circuit CRC1R, C5R, C4R, C1R, and C0R are supplied to the second CRC encoding circuit CRC2R′.

At the same time, CRC intermediate calculation results C5L, C4L, C1L, and C0L from the second encoding circuit CRC1L′ in the left side region (LEFT) of the chip are supplied to the second CRC encoding circuit CRC2R′.

The second. CRC encoding circuit CRC2R′ receives the CRC intermediate calculation results and generates CRC bits C[5], C[4], C[1], and C[0]. Among these, the CRC bits C[4] and C[0] to be output from the output pin DQ3 are stored in the CRC bit output buffer FIFO3_C, in the output buffer of the output pin DQ3.

CRC bits and data groups stored in the output buffers FIFO3_D0, FIFO3_D1, and FIFO3_C are output responsive to clock rising edge and falling edge.

Output order is as follows:

data bits D[36], D[32], D[28], and D[24] are output from the first output buffer FIFO3_D0;

after that, the CRC bit C[4] is output from the CRC output buffer FIFO3_C;

next, data bits D[20], D[16], D[12], and D[8] are output from the second output buffer FIFO3_D1; and

finally, the CRC bit C[0] is output from the CRC output buffer FIFO3_C.

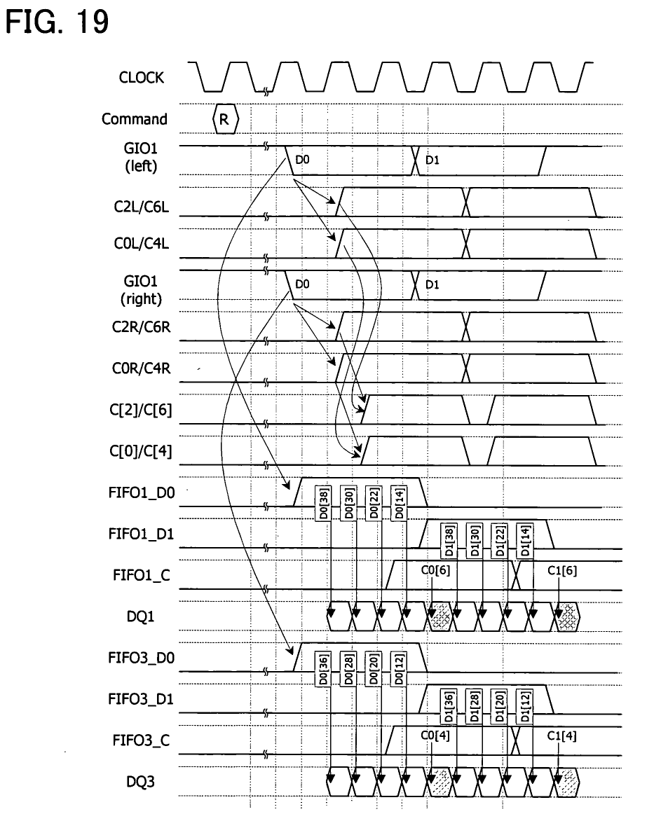

Next, operation with the ×8 configuration will be described, with reference to FIG. 19.

According to an address and a read command sampled responsive to a clock edge, data D0[39:8] corresponding to a selected address are supplied to the data output lines GIO1 on the left and right sides of the chip.

After the data D0[39:8] are output, subsequent data D1[39:8] are supplied to the data output lines GIO1.

The data D0 and D1 supplied to the data output lines GIO1 are delivered to the common data output lines GIO2 via the multiplexers MUX8.

In the left side region (LEFT) of the chip, data groups output to the common data output line GIO2 are supplied to the output buffers FIFO for the output pins DQ0, DQ1, DQ4, and DQ5.

Here, an output buffer FIFO corresponding to DQ1 is described as an example.

Data D0[38], D0[30], D0[22], and D0[14] output from among a first data group the first 4 times (1D to 4D), are stored in the first output buffer FIFO1_D0, and data D1[38], D1[30], D1[22], and D1[14], output from among a second data group 4 times (5D to 8D) after a check bit, are stored in the second output buffer FIFO1_D1.

At the same time, the output data D0 and D1 of the common data output line GIO2 are supplied to the first CRC encoding circuit CRC1L′.

The first CRC encoding circuit CRC1L′, first, produces the CRC intermediate calculation results C0L, C1L, C2L . . . , C7L corresponding to the data group D0.

Among the CRC intermediate output results output from the first CRC encoding circuit CRC1L′, C7L, C6L, C3L, and C2L are supplied to the second CRC encoding circuit CRC2L′.

At the same time, the CRC intermediate calculation results C7R, C6R, C3R, and C2R, from the second encoding circuit CRC1R′ in the right side region (RIGHT) of the chip, are supplied to the second CRC encoding circuit CRC2L′.

The second CRC encoding circuit CRC2L′ receives the CRC intermediate calculation results and generates the CRC bits C0[7], C0[6], C0[3], and C0[2] corresponding to the data group D0. Among these, the CRC bit C0[6] to be output from the output pin DQ1 is stored in the CRC bit output buffer FIFO1_C, in the output buffer of the output pin DQ1.

After that, a similar operation is performed on the data group D1 supplied to the common data output line GIO2, and the CRC bit C1[6] corresponding to the data group D1 is stored in the CRC bit output buffer FIFO1_C of the output pin DQ1.

CRC bits and data groups stored in the output buffers FIFO1_D0, FIFO1_D1, and FIFO1_C are output responsive to clock rising edge and falling edge.

Output order is as follows:

data bits D0[38], D0[30], D0[22], and D0[14] are output from the first output buffer FIFO1_D0;

after that, the CRC bit C0[6] is output from the CRC output buffer FIFO1_C;

next, data bits D1[38], D1[30], D1[22], and D1[14] are output from the second output buffer FIFO1_D1; and

finally, the CRC bit C1[6] is output from the CRC output buffer FIFO1_C.

In the same way, in the right side region (RIGHT) of the chip, data groups output to the common data output path GIO2 are supplied to the output buffers FIFO for the output pins DQ2, DQ3, DQ6, and DQ7.

An output buffer FIFO corresponding to DQ3 will be described as an example.

Data D0[36], D0[28]; D0[20], and D0[12] output from among a first data group the first 4 times (1D to 4D), are stored in the first output buffer FIFO3_D0, and data D1[36], D1[28], D1[20], and D1[12] output from among a second data group 4 times (5D to 8D), after a check bit, are stored in the second output buffer FIFO3_D1.

At the same time, the output data D0 and D1 of the common data output line GIO2 are supplied to the first CRC encoding circuit CRC1R′.

The first CRC encoding circuit CRC1R′, first, produces the CRC intermediate calculation results C0R, C1R, C2R . . . , C7R corresponding to the data group D0.

Among the CRC intermediate calculation results output from the first CRC encoding circuit CRC1R′, C5R, C4R, C1R, and C0R are supplied to the second CRC encoding circuit CRC2R′.

At the same time, CRC intermediate calculation results C5L, C4L, C1L, and C0L from the first encoding circuit CRC1L′ in the left side region (LEFT) of the chip are supplied to the second CRC encoding circuit CRC2R′.

The second CRC encoding circuit CRC2R′ receives the CRC intermediate calculation results and generates the CRC bits C0[5], C0[4], C0[1], and C0[0] corresponding to the data group D0. Among these, the CRC bit C0[4] to be output from the output pin DQ3 is stored in the CRC bit output buffer FIFO3_C, in the output buffer of the output pin DQ3.

After that, a similar operation is performed on the data group D1 supplied to the common data output line GIO2, and the CRC bit C1[4] corresponding to the data group D1 is stored in the CRC bit output buffer FIFO3_C of the output pin DQ3. CRC bits and data groups stored in the output buffers FIFO3_D0, FIFO3_D1, and FIFO3_C are output responsive to clock rising edge and falling edge.

Output order is as follows:

data bits D0[36], D0[28], D0[20], and D0[12] are output from the first output buffer FIFO3_D0;

after that, the CRC bit C0[4] is output from the CRC output buffer FIFO3_C;

next, data bits D1[36], D1[28], D1[20], and D1[12] are output from the second output buffer FIFO1_D1; and

finally, the CRC bit C1[4] is output from the CRC output buffer FIFO3_C.

Effects and features of the present exemplary embodiment will be described.

In a chip handling ×4 and ×8 configurations, in correspondence with the data output order in which data output from DQ0 and DQ1, or DQ2 and DQ3, in the ×4 configuration, are output from DQ0, DQ1, DQ4, and DQ5, or DQ2, DQ3, DQ6, and DQ7, in the ×8 configuration, data addresses inside the chip are made same in the ×4 and ×8 configurations. By arranging DQ4 and DQ5 adjacent to data pins DQ0 and DQ1, and arranging DQ6 and DQ7 adjacent to data pins DQ2 and DQ3, it is possible to use common CRC encoding circuits, for the ×4 and ×8 configurations, thereby reducing chip area and reducing the number of data buses crossing between left and right of the chip.

By switching data supplied to CRC intermediate calculation result transfer paths that cross between the CRC encoding circuits, according to the word configuration, it is possible to reduce the number of wires.

Conversely, in a chip handling ×4 and ×8 chip configurations, in which DQ4 and DQ5 are arranged adjacent to output pins DQ0 and DQ1, and DQ6 and DQ7 are arranged adjacent to DQ2 and DQ3, by setting a data output order to such an order in which data output from DQ0 and DQ1, or DQ2 and DQ3, in the ×4 configuration, are output from DQ0, DQ1, DQ4, and DQ5, or DQ2, DQ3, DQ6, and DQ7, in the ×8 configuration, it becomes possible to use common CRC encoding circuits, and to reduce chip area.

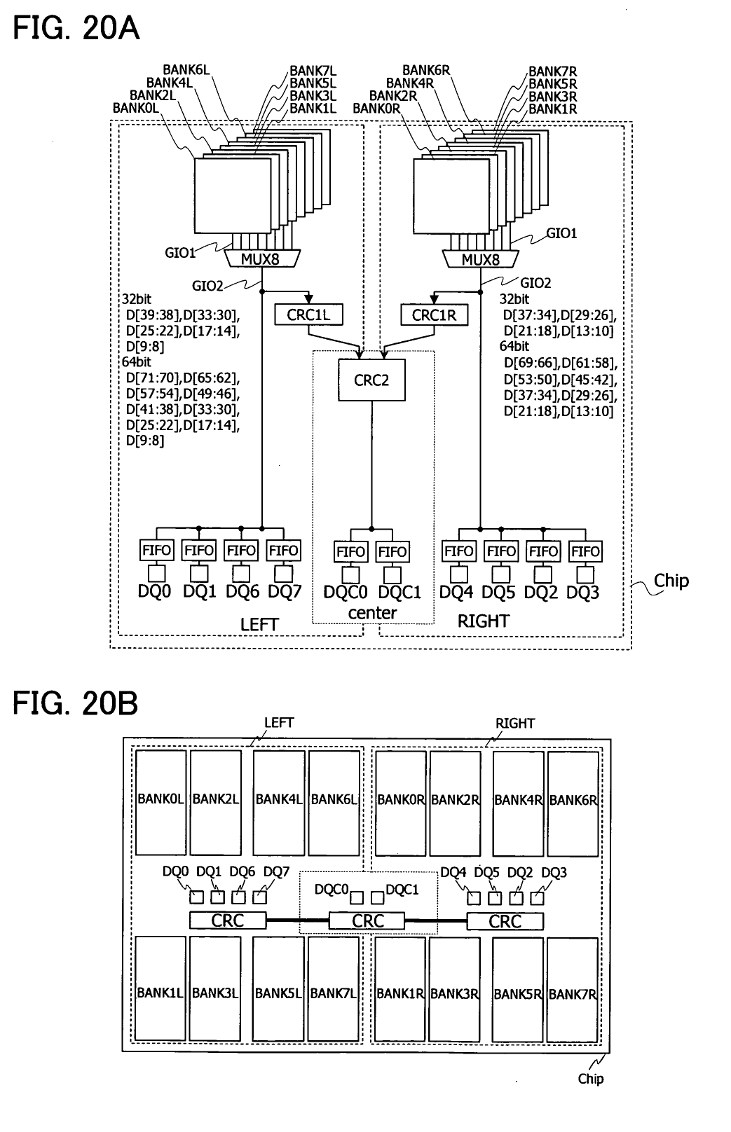

FIGS. 20A and 20B show a configuration of a modified example of the first exemplary embodiment. Referring to FIGS. 20A and 20B, in this modified example, similar to the first exemplary embodiment, in a chip handling ×4 and ×8 configurations, in correspondence with data output order in which data output from DQ0 and DQ1, or DQ2 and DQ3, in the ×4 configuration, are output from DQ0, DQ1, DQ6, and DQ7, or DQ2, DQ3, DQ4, and DQ5, in the ×8 configuration, data addresses inside the chip are made the same in the ×4 and ×8 configurations. By arranging DQ6 and DQ7 adjacent to output pins DQ0 and DQ1, and arranging DQ4 and DQ5 adjacent to output pins DQ2 and DQ3, output pins DQC0 and DQC1 dedicated to outputting CRC bits are arranged in the center of the chip.

A second CRC encoding circuit CRC2, the CRC bit output pins DQC0 and DQC1, and output buffers FIFO for the output pins are arranged in a center region of the chip.

In the ×4 configuration, besides the data output pins DQ0, DQ1, DQ2, and DQ3, a CRC output pin DQC0 is used.

In the ×8 configuration, besides the data output pins DQ0, DQ1, DQ2, DQ3, DQ4, DQ5, DQ6, and DQ7, the CRC output pins DQC0 and DQC1 are used. Other arrangements are similar to the above-mentioned first exemplary embodiment.

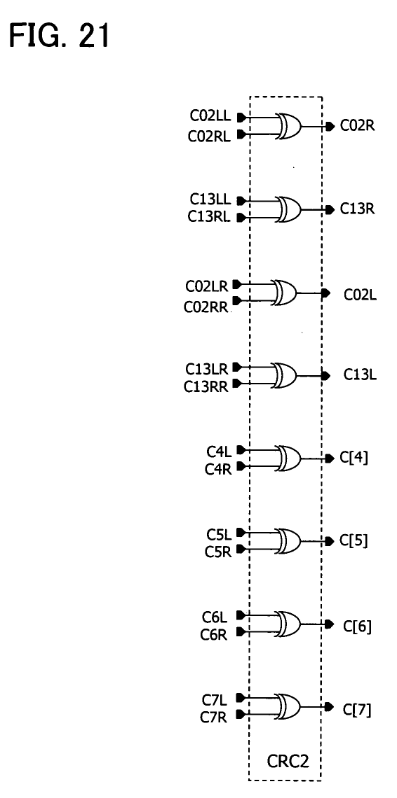

FIG. 21 is a diagram showing an example of a configuration of the second CRC encoding circuit CRC2.

Using CRC intermediate calculation results output from first CRC encoding circuits CRC1L and CRC1R on the left and right, CRC code bits C[7:0] are generated.

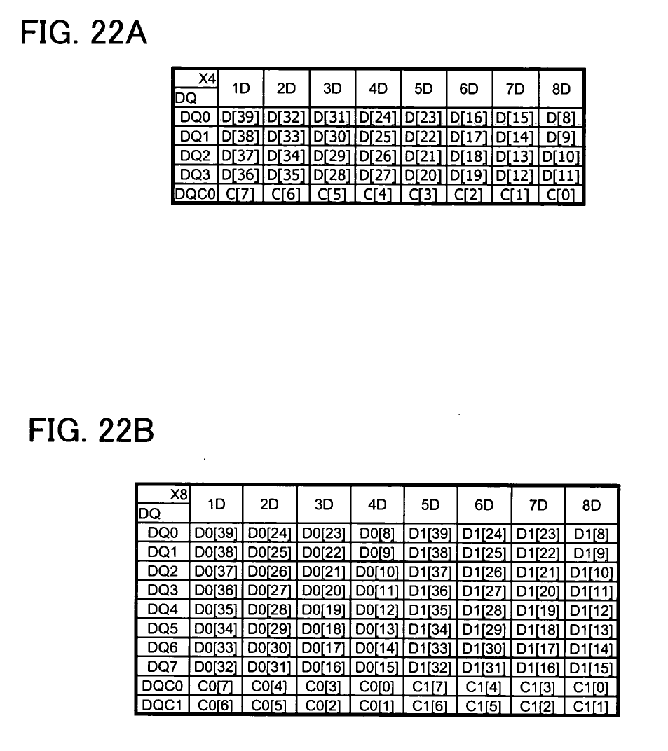

FIGS. 22A and 22B show relationships of data numbers of data groups, output pins, and data output order, for the two word configurations ×4 and ×8 implemented in the chip of FIGS. 20A and 20B. Here, the CRC encoding assumes a configuration in which 8-bit CRC code is added with respect to 32-bit data bits.

FIG. 22A shows, in case of the word configuration being ×4, order of data externally output from the data output pins DQ0, DQ1, DQ2, and DQ3, and output order of CRC bits.

In the present exemplary embodiment, with regard to output data groups, for 32 bits as far as data bits D[39]-D[8], as shown in the drawing, data output order for data numbers D[39], D[38], D[37], D[36], D[35], D[34], D[33], D[32], . . . , D[9], and D[8], in descending order, is DQ0, DQ1, DQ2, DQ3, DQ3, DQ2, DQ1, DQ0, . . . , DQ1, and DQ0.

Among data bit output timing 1D, 2D, 3D, 4D, 5D, 6D, 7D, 8D, with regard to odd number output (1D, 3D, 5D, 7D), data numbers are in descending order, with respect to the order DQ0, DQ1, DQ2 and DQ3, and with regard to even number output (2D, 4D, 6D, 8D), data numbers are in descending order, with respect to the order DQ3, DQ2, DQ1, and DQ0.

FIG. 22B shows, in case of the word configuration being ×8, order of data externally output from the data output pins DQ0, DQ1, DQ2, DQ3, DQ4, DQ5, DQ6, and DQ7, and output order of CRC bits.

In the present exemplary embodiment, two data bit groups, D0[39]-D0[8] and D1[39]-D1[8] each of 32 bits, are output from the data output pins DQ0, DQ1, DQ2, DQ3, DQ4, DQ5, DQ6, and DQ7, CRC bit groups C0[7]-C0[0] and C1[7]-C1[0], each of 8 bits, corresponding to data groups D0[39:8] and D1[39:8] are output from the CRC output pins DQC0 and DQC1.

Similar to the abovementioned FIG. 22A, data output order, for data D0[39], D0[38], D0[37], D0[36], D0[35], D0[34], D0[33], D0[32], D0[31], D0[30], D0[29], D0[28], D0[27], D0[26], D0[25], D0[24], . . . , D0[9] and D0[8], and D1[39], D1[38], D1[37], D1[36], D1[35], D1[34], D1[33], D1[32], D1[31], D1[30], D1[29], D1[28], D1[27], D1[26], D1[25], D1[24], . . . , D1[9], D1[8], is DQ0, DQ1, DQ2, DQ3, DQ4, DQ5, DQ6, DQ7, DQ7, DQ6, DQ5, DQ4, DQ3, DQ2, DQ1, DQ0, . . . , DQ1 and DQ0. Among data output timing 1D, 2D, 3D and 4D, with regard to odd number output (1D, 3D, 5D, 7D), data numbers are in descending order, with respect to the order DQ0, DQ1, DQ2, DQ3, DQ4, DQ5, DQ6 and DQ7, and with regard to even number output (2D, 4D, 6D, 8D), data numbers are in descending order, with respect to the order DQ7, DQ6, DQ5, DQ4, DQ3, DQ2, DQ1 and DQ0.

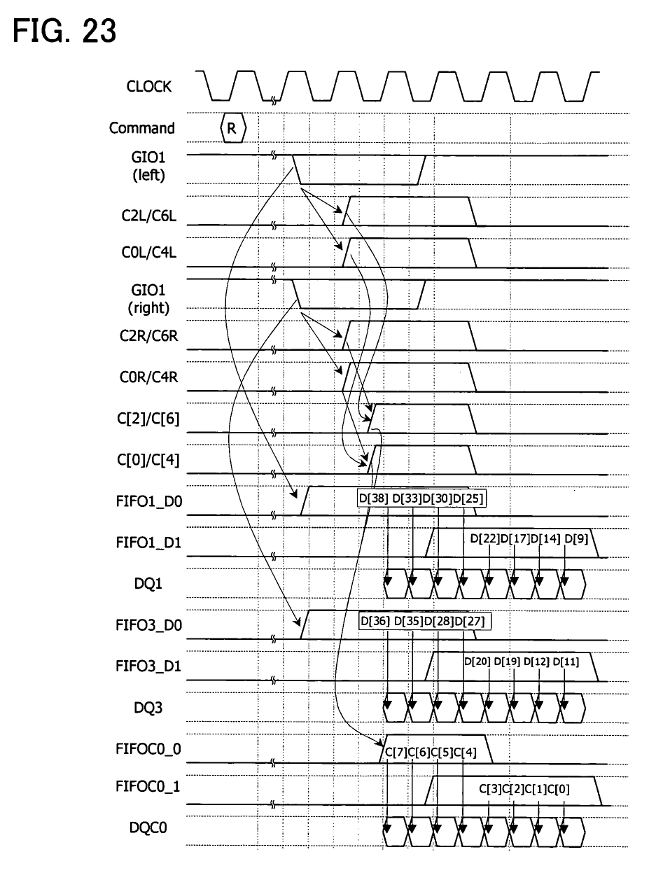

Next, a description will be given concerning operation of the present exemplary embodiment for an ×4 configuration, using FIG. 23. The output pin DQ1 in the left side region (LEFT) of the chip, the output pin DQ3 in the right side region, and the CRC output pin DQC0 in the central region of the chip will be described.

In accordance with an address and read command sampled responsive to a clock edge, data corresponding to a selected address are supplied to the data output lines GIO1 on the left and right sides of the chip, and until CRC intermediate calculation results are output, by the first CRC encoding circuit, the description is similar to the above described first exemplary embodiment.

In the left side region (LEFT) of the chip, data groups delivered to a common data output line GIO2 are supplied to output buffers FIFO for the output pins DQ0 and DQ1.

An output buffer FIFO corresponding to DQ1 will be described as an example.

Data D[38], D[33], D[30], and D[25] output the first 4 times (1D to 4D), are stored in a first output buffer FIFO1_D0, and data D[22], D[17], D[14], and D[9], output 4 times (5D to 8D) after a check bit, are stored in a second output buffer FIFO1_D1.

At the same time, data delivered to the common data output line GIO2 are supplied to the first CRC encoding circuit CRC1L.

The CRC intermediate calculation results C0L, C1L, C2L . . . , and C7L are output from the first CRC encoding circuit CRC1L. The outputs of the CRC intermediate calculation results are supplied to the second CRC encoding circuit CRC2.

With regard to operation of the right side region (RIGHT) of the chip, data groups delivered to a common data output line GIO2 are supplied to output buffers FIFO for the output pins DQ2 and DQ3.

An output buffer FIFO corresponding to DQ3 will be described as an example.

Data D[36], D[35], D[28], and D[27] output the first 4 times (1D to 4D), are stored in a first output buffer FIFO3_D0, and data D[20], D[19], D[12], and D[11], output 4 times (5D to 8D) after a check bit, are stored in a second output buffer FIFO3_D1.

At the same time, data of the common data output line GIO2 are supplied to the first CRC encoding circuit CRC1R.

The CRC intermediate calculation results C0R, C1R, C2RL . . . , and C7R are output from the first CRC encoding circuit CRC1R. The outputs of the CRC intermediate calculation results are supplied to the second CRC encoding circuit CRC2.

In the second CRC encoding circuit CRC2 receives the CRC intermediate calculation results, and generates CRC bits C[7:0].

The generated CRC bits are stored in output buffers FIFOC0_0 and FIFOC0_1 for the CRC bit output pin DQC0.

CRC bits and data groups stored in the output buffers FIFO1_D0, FIFO1_D1, and FIFO1_C are output responsive to clock rising edge and falling edge.

Output order is as follows:

data bits D[38], D[33], D[30], and D[25] from the first output buffer FIFO1_D0 are delivered to the output pin DQ1; at the same time, data bits D[36], D[35], D[28], and D[27] are output from the first output buffer FIFO3_D0 to the output pin DQ3 in the right side region (RIGHT) of the chip; and

CRC bits C[7], C[6], C[5], and C[4] are output from the output pin DQC0 in the central region of the chip.

After that, data bits D[22], D[17], D[14], and D[9] are output from the second output buffer FIFO1_D1 to the output pin DQ1 in the left side region (LEFT) of the chip, data bits D[20], D[19], D[12], and D[11] are output from the second output buffer FIFO3_D1 to the output pin DQ3 in the right side region (RIGHT) of the chip, and CRC bits C[7], C[6], C[5], and C[4] are output from the output pin DQC0 in the central region of the chip.

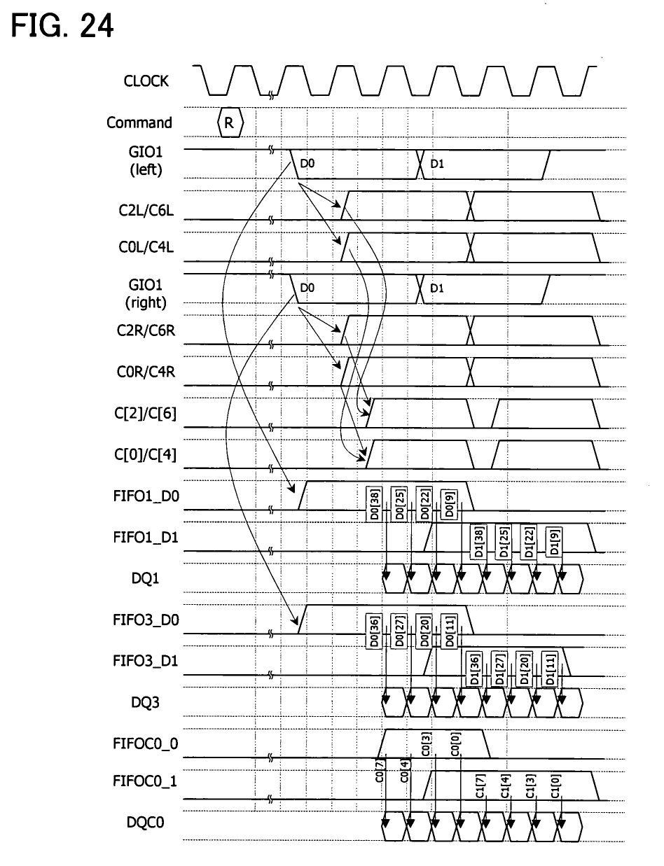

Next, operation with the ×8 configuration will be described, with reference to FIG. 24. The output pin DQ1 in the left side region (LEFT) of the chip, the output pin DQ3 in the right side region, and the CRC output pin DQC0 in the central region of the chip will be described. In accordance with an address and read command sampled responsive to a clock edge, data D0[39:8] corresponding to a selected address are supplied to the data output lines GIO1 on the left and right sides of the chip. After the data D0[39:8] are output, subsequent data D1[39:8] are supplied to the data output lines GIO1.

The data D0 and D1 delivered to the data output lines GIO1 are delivered to the common data output lines GIO2 via multiplexers MUX8.

In the left side region (LEFT) of the chip, data groups delivered to the common data output line GIO2 are supplied to the output buffers FIFO for the output pins DQ0, DQ1, DQ6, and DQ7.

An output buffer FIFO corresponding to DQ1 will be described as an example.

Data D0[38], D0[25], D0[22], and D0[9] output from among a first data group the first 4 times (1D to 4D), are stored in the first output buffer FIFO1_D0, and data D1[38], D1[25], D1[22], and D1[9], output from among a second data group 4 times (5D to 8D) after a check bit, are stored in the second output buffer FIFO1_D1. At the same time the output data D0 and D1 of the common data output line are supplied to the first CRC encoding circuit CRC1L.

First, the CRC intermediate calculation results C0L, C1L, C2L . . . , and C7L corresponding to the data group D0 are output from the first CRC encoding circuit CRC1L. The CRC intermediate calculation results C0L, C1L, C2L . . . and C7L corresponding to D1 are then output. The outputs of the CRC intermediate calculation results are supplied to the second CRC encoding circuit CRC2.

In the right side region (RIGHT) of the chip, data groups output to the common data output line GIO2 are supplied to the output buffers FIFO for the output pins DQ2, DQ3, DQ4, and DQ5. An output buffer FIFO corresponding to DQ3 will be described as an example.

Data D0[36], D0[27], D0[20], and D0[11] output from among a first data group the first 4 times (1D to 4D), are stored in the first output buffer FIFO3_D0, and data D1[36], D1[27], D1[20], and D1[11], output from among a second data group 4 times (5D to 8D) after a check bit, are stored in the second output buffer FIFO3_D1. At the same time the output data D0 and D1 of the common data output line are supplied to the first CRC encoding circuit CRC1R.

First, the CRC intermediate calculation results C0R, C1R, C2R . . . , and C7R corresponding to the data group D0 are output.

The CRC intermediate calculation results C0R, C1R, C2R . . . and C7R corresponding to D1 are then output. The outputs of the CRC intermediate calculation results are supplied to the second CRC encoding circuit CRC2.

The second CRC encoding circuit CRC2 receives the CRC intermediate calculation results and generates CRC bits C0[7:0] corresponding to the data group D0 and CRC bits C1[7:0] corresponding to the data group D1.

The generated CRC bits C0[7:0] are stored in the output buffers FIFOC0_0 and FIFOC1_0 for the CRC bit output pins DQC0 and DQC1.

The CRC bits C1[7:0] corresponding to the data group D1 are then stored in output buffers FIFOC0_1 and FIFOC1_1 for the CRC bit output pins DQC0 and DQC1.

CRC bits and data groups thus stored in the output buffers FIFO1_D0, FIFO1_D1, FIFO3_D0, FIFO3_D1, FIFOC0_0, FIFOC0_1, FIFOC1_0, and FIFOC1_1 are output responsive to clock rising edge and falling edge.

Output order is as follows:

data bits D0[38], D0[25], D0[22], and D0[9] are output from the first output buffer FIFO1_D1;

at the same time, data bits D0[36], D0[27], D0[20], and D0[11] are output from the first output buffer FIFO3_D0 to the output pin DQ3 in the right side region (RIGHT) of the chip; and

CRC bits C0[7], C0[4], C0[3], and C0[0] are output from the output pin DQC0 in the central region of the chip.

After that, data bits D1[38], D1[25], D1[22], and D1[9] are output from the second output buffer FIFO1_1D1 to the output pin DQ1 in the left side region (LEFT) of the chip;

at the same time, data bits D1[36], D1[27], D1[20], and D1[11] are output from the second output buffer FIFO3_D1 to the output pin DQ3 in the right side region (RIGHT) of the chip; and

CRC bits C1[7], C1[4], C1[3], and C1[0] are output from the output pin DQC0 in the central region of the chip.

Effects and features of the present exemplary embodiment will be described. Similar to the abovementioned first exemplary embodiment, in a chip handling ×4 and ×8 chip configurations, in correspondence with data output order in which data output from DQ0 and DQ1, or DQ2 and DQ3, in the ×4 configuration, are output from DQ0, DQ1, DQ6, and DQ7, or DQ2, DQ3, DQ4, and DQ5, in the ×8 configuration, data addresses inside the chip are made the same in the ×4 and ×8 configurations. By arranging DQ6 and DQ7 adjacent to output pins DQ0 and DQ1, and arranging DQ4 and DQ5 adjacent to output pins DQ2 and DQ3, it is possible to use a common CRC encoding circuit, in the ×4 and ×8 configurations, so that chip area is able to be reduced and the number of data buses crossing between left and right of the chip is able to be reduced.

Conversely, in a chip handling ×4 and ×8, in a configuration in which DQ6 and DQ7 are arranged adjacent to output pins DQ0 and DQ1, and DQ4 and DQ5 are arranged adjacent to DQ2 and DQ3, by setting a data output order to such an order in which data output order is so set that data output from DQ0 and DQ1, or DQ2 and DQ3, in the ×4 configuration, are output from DQ0, DQ1, DQ6, and DQ7, or DQ2, DQ3, DQ4, and DQ5, in the ×8 configuration, it becomes possible to use a common CRC encoding circuit, and to reduce chip area.

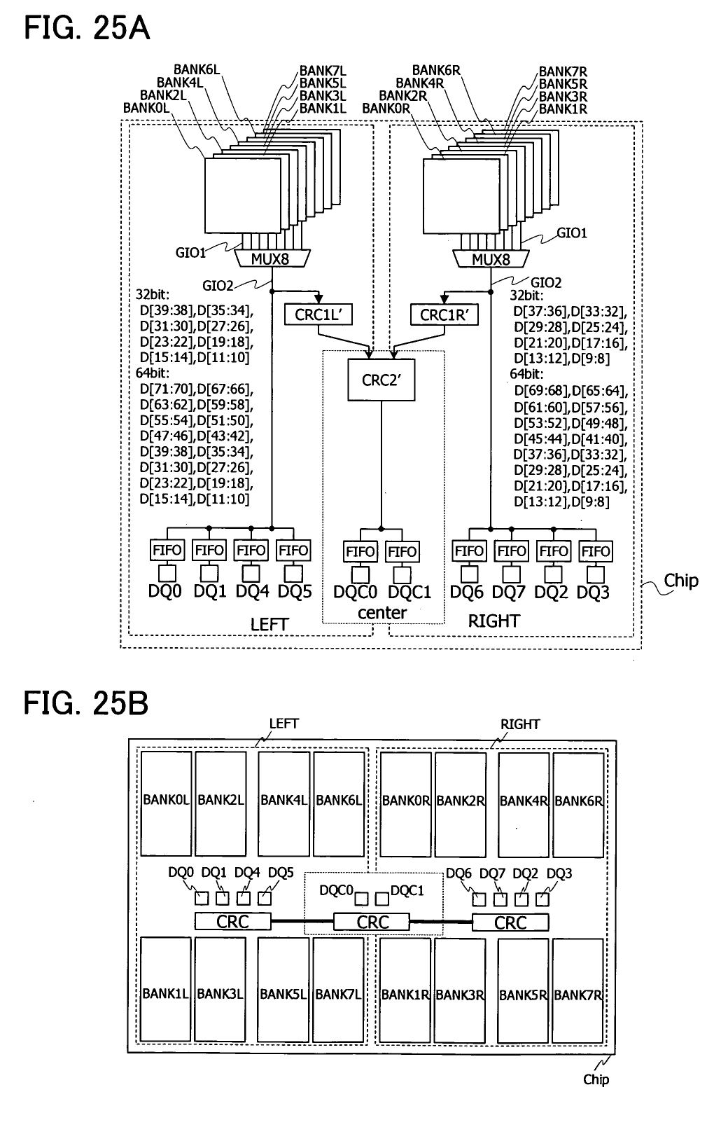

FIGS. 25A and 25B show a modified example of the second exemplary embodiment of the present invention. In this modified example, similar to the second exemplary embodiment, in a chip handling ×4 and ×8 configurations, in correspondence with the data output order in which data output from DQ0 and DQ1, or DQ2 and DQ3, in the ×4 configuration, are output from DQ0, DQ1, DQ4, and DQ5, or DQ2, DQ3, DQ6, and DQ7, in the ×8 configuration, data addresses inside the chip are made the same in the ×4 and ×8 configurations. DQ4 and DQ5 are arranged adjacent to the output pins DQ0 and DQ1, and DQ6 and DQ7 are arranged adjacent to the output pins DQ2 and DQ3.

Output pins DQC0 and DQC1 dedicated to outputting CRC bits are arranged in the center of the chip. In this configuration, a second CRC encoding circuit CRC2′, CRC bit output pins DQC0 and DQC1, and output buffers FIFO for these output pins are arranged in a center region of the chip.

In the ×4 configuration, besides the data output pins DQ0, DQ1, DQ2, and DQ3, a CRC output pin DQC0 is used.

On the other hand, in the ×8 configuration, besides the data output pins DQ0, DQ1, DQ2, DQ3, DQ4, DQ5, DQ6, and DQ7, CRC output pins DQC0 and DQC1 are used. Other arrangements are similar to the abovementioned second exemplary embodiment.

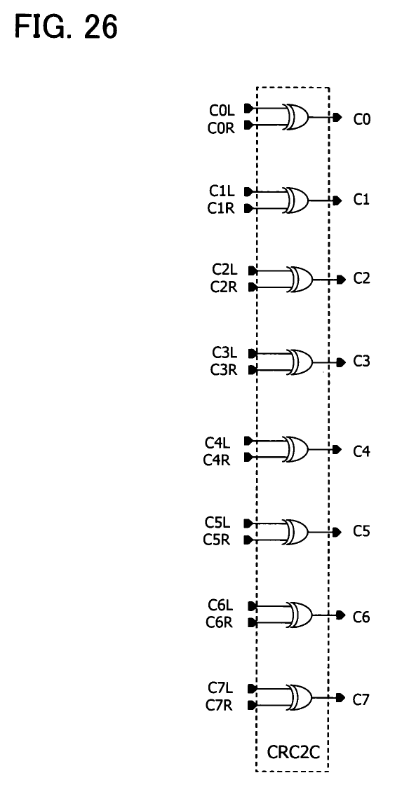

FIG. 26 is a diagram showing an example of a configuration of the second CRC encoding circuit CRC2′. Using CRC intermediate calculation results output from first CRC encoding circuits CRC1L′ and CRC1R′ on the left and right, CRC encoding bits C[7:0] are generated.

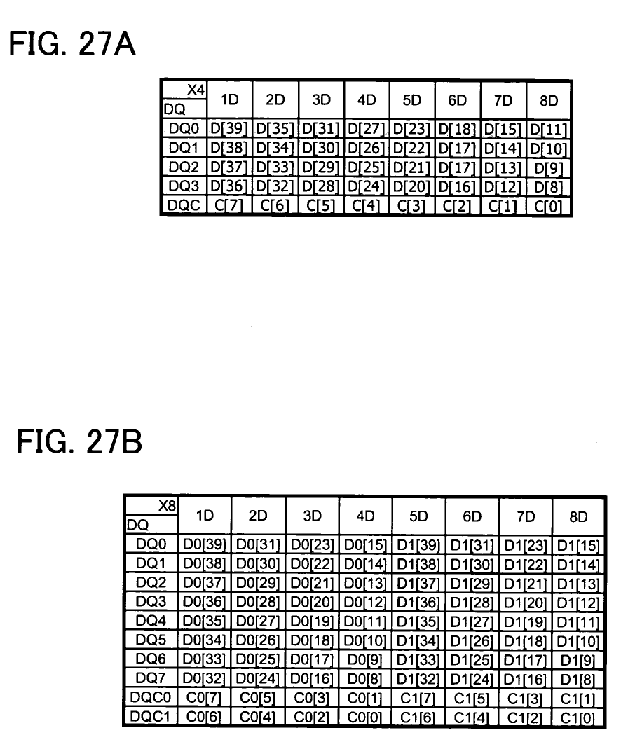

FIGS. 27A and 27B show relationships of data numbers of data groups, output pins, and data output order, for two word configurations ×4 and ×8 implemented in the chip of FIGS. 25A and 25B. The CRC encoding assumes a configuration in which 8-bit CRC code is added with respect to 32-bit data bits.

FIG. 27A shows, in case of the word configuration being ×4, order of data externally output from the data output pins DQ0, DQ1, DQ2, and DQ3, and output order of CRC bits of the CRC output pins.

In the present exemplary embodiment, similar to the second exemplary embodiment, with regard to output data groups, for 32 bits as far as data bits D[39]-D[8], data output order, as shown in the drawing, for data numbers D[39], D[38], D[37], D[36], D[35], D[34], D[33], D[32], . . . , D[9] and D[8], in descending order, is as in DQ0, DQ1, DQ2, DQ3, DQ0, DQ1, DQ2, DQ3, . . . DQ2 and DQ3. With any data bit output timing 1D, 2D, 3D, 4D, 5D, 6D, 7D and 8D, data numbers are in descending order, with respect to the order of output pins DQ0, DQ1, DQ2 and DQ3.

FIG. 27B shows, in case the word configuration is ×8, order of data externally output from the data output pins DQ0, DQ1, DQ2, DQ3, DQ4, DQ5, DQ6, and DQ7, and output order of CRC bits.

Two data bit groups, D0[39]-D0[8] and D1[39]-D1[8], each of 32 bits, are output from the output pins DQ0, DQ1, DQ2, DQ3, DQ4, DQ5, DQ6, and DQ7, and CRC bit groups C0[7]-C0[0] and C1[7]-C1[0], each of 8 bits, corresponding to data groups D0[39:8] and D1[39:8] are output from the CRC output pins DQC0 and DQC1.

Data output order, similar to FIG. 27A described above, for data D0[39], D0[38], D0[37], D0[36], D0[35], D0[34], D0[33], D0[32], D0[31], D0[30], D0[29], D0[28], D0[27], D0[26], D0[25], D0[24], . . . , D0[9] and D0[8], and D1[39], D1[38], D1[37], D1[36], D0[35], D1[34], D1[33], D1[32], D1[31], D1[30], D1[29], D1[28], D1[27], D1[26], D1[25], D1[24], . . . , D1[9] and D1[8], in descending order, is DQ0, DQ1, DQ2, DQ3, DQ4, DQ5, DQ6, DQ7, DQ0, DQ1, DQ2, DQ3, DQ4, DQ5, DQ6, DQ7, and DQ0. For any data output timing 1D, 2D, 3D, and 4D, data numbers are in descending order, with respect to the order DQ0, DQ1, DQ2, DQ3, DQ4, DQ5, DQ6, and DQ7.

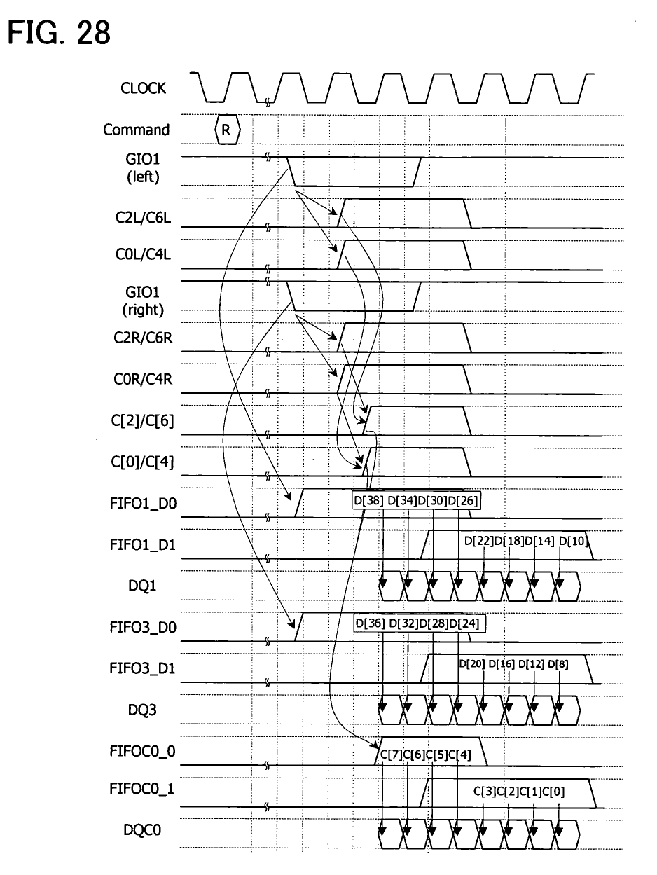

Next, a description is given concerning operation of the present exemplary embodiment for an ×4 configuration, with reference to FIG. 28. The output pin DQ1 in the left side region (LEFT) of the chip, the output pin DQ3 in the right side region, and the CRC output pin DQC0 in the central region of the chip will be described.

In accordance with an address and read command sampled responsive to a clock edge, data corresponding to a selected address are supplied to the data output lines GIO1 on the left and right sides of the chip, and until CRC intermediate calculation results are output, by the first CRC encoding circuits, the description is similar to the abovementioned second exemplary embodiment.

In the left side region (LEFT) of the chip, data groups output to the common data output line GIO2 are supplied to the output buffers FIFO for the output pins DQ0 and DQ1.

An output buffer FIFO corresponding to DQ1 will be described as an example.

Data D[38], D[34], D[30], and D[26] output the first 4 times (1D to 4D), are stored in a first output buffer FIFO1_D0, and data D[22], D[18], D[14], and D[10], output 4 times (5D to 8D) after a check bit, are stored in a second output buffer FIFO1_D1. At the same time, a common data output line is supplied to the first CRC encoding circuit CRC1L′.

The CRC intermediate calculation results C0L, C1L, C2L . . . , and C7L are output from the first CRC encoding circuit CRC1L′. The outputs of the CRC intermediate calculation results are supplied to the second CRC encoding circuit CRC2′.

With regard to the right side region (RIGHT) of the chip, data groups output to the common data output line GIO2 are supplied to the output buffers FIFO for the output pins DQ2 and DQ3.

An output buffer FIFO corresponding to DQ3 will be described as an example.

Data D[36], D[32], D[28], and D[24] output the first 4 times (1D to 4D), are stored in a first output buffer FIFO3_D0, and data D[20], D[16], D[12], and D[8], output 4 times (5D to 8D) after a check bit, are stored in a second output buffer FIFO3_D1. At the same time, a common data output line is supplied to the first CRC encoding circuit CRC1R′.

The CRC intermediate calculation results C0R, C1R, C2RL . . . , and C7R are output from the first CRC encoding circuit CRC1R′. The outputs of the CRC intermediate calculation results are supplied to a second CRC encoding circuit CRC2′.

The second CRC encoding circuit CRC2′ receives the CRC intermediate calculation results and generates CRC bits C[7:0]. The generated CRC bits are stored in output buffers FIFOC0_0 and FIFOC0_1 for the CRC bit output pin DQC0.

CRC bits and data groups stored in the output buffers FIFO1_D0, FIFO1_D, and FIFO1_C are output responsive to clock rising edge and falling edge.

Output order is as follows:

data bits D[38], D[34], D[30], and D[26] are output from the first output buffer FIFO1_D0 to the output pin DQ1;

at the same time, data bits D[36], D[32], D[28], and D[24] are output from the first output buffer FIFO3_D0 to the output pin DQ3 in the right side region (RIGHT) of the chip; and

CRC bits C[7], C[6], C[5], and C[4] are output from the output pin DQC0 in the central region of the chip.

After that, data bits D[22], D[17], D[14], and D[9] are output from the second output buffer FIFO1_D1 to the output pin DQ1 in the left side region (LEFT) of the chip, data bits D[20], D[16], D[12], and D[8] are output from the second output buffer FIFO3_D1 to the output pin DQ3 in the right side region (RIGHT) of the chip, and CRC bits C[7], C[6], C[5], and C[4] are output from the output pin DQC0 in the central region of the chip.

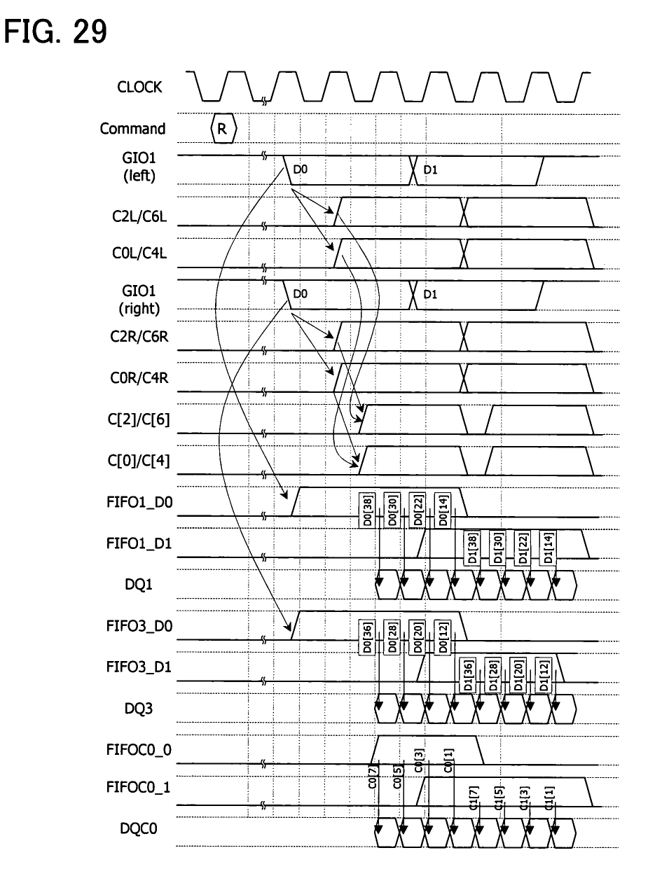

Next, operation with ×8 will be described, with reference to FIG. 29. The output pin DQ1 in the left side region (LEFT) of the chip, the output pin DQ3 in the right side region, and the CRC output pin DQC0 in the central region of the chip will be described.

In accordance with an address and read command sampled responsive to a clock edge, data D0[39:8] corresponding to a selected address are supplied to the data output lines GIO1 on the left and right sides of the chip.

After the data D0[39:8] are output, subsequent data D1[39:8] are supplied to the data output lines GIO1. The data D0 and D1 supplied to the data output lines GIO1 are delivered to the common data output lines GIO2 via multiplexers MUX8.

In the left side region (LEFT) of the chip, data groups output to the common data output line GIO2 are supplied to the output buffers FIFO for the output pins DQ0, DQ1, DQ4, and DQ5. An output buffer FIFO corresponding to DQ1 will be described as an example.

Data D0[38], D0[30], D0[22], and D0[14], output from among a first data group the first 4 times (1D to 4D), are stored in the first output buffer FIFO1_D0, and data D1[38], D1[30], D1[22], and D1[14], output from among a second data group 4 times (5D to 8D) after a check bit, are stored in the second output buffer FIFO1_D1.

At the same time, the output data D0 and D1 of the common data output line GIO2 are supplied to the first CRC encoding circuit CRC1L′.

First, the CRC intermediate calculation results C0L, C1L, C2L, . . . , and C7L corresponding to the data group D0 are output from the first CRC encoding circuit CRC1L′. The CRC intermediate calculation results C0L, C1L, C2L, . . . and C7L corresponding to D1 are then output. The outputs of the CRC intermediate calculation results are supplied to the second CRC encoding circuit CRC2′.

In the right side region (RIGHT) of the chip, data groups output to the common data output line GIO2 are supplied to the output buffers FIFO for the output pins DQ2, DQ3, DQ6, and DQ7. An output buffer FIFO corresponding to DQ3 will be described as an example.

Data D0[36], D0[28], D0[20], and D0[12], output from among a first data group the first 4 times (1D to 4D), are stored in the first output buffer FIFO3_D0, and data D1[36], D1[28], D1[20], and D1[12], output from among a second data group 4 times (5D to 8D) after a check bit, are stored in the second output buffer FIFO3_D1. At the same time the output data D0 and D1 of the common data output line are supplied to the first CRC encoding circuit CRC1R′.

First, the CRC intermediate calculation results C0R, C1R, C2R, . . . , and C7R corresponding to the data group D0 are output from the first CRC encoding circuit CRC1R′. The CRC intermediate calculation results C0R, C1R, C2R, . . . , and C7R corresponding to D1 are then output. The outputs of the CRC intermediate calculation results are supplied to a second CRC encoding circuit CRC2′.

In the second CRC encoding circuit CRC2′ receives the CRC intermediate calculation results, and generates CRC bits C0[7:0] corresponding to the data group D0 and CRC bits C1[7:0] corresponding to the data group D1.

The generated CRC bits C0[7:0] are stored in the output buffers FIFOC0_0 and FIFOC1_0 for the CRC bit output pins DQC0 and DQC1.

The CRC bits C1[7:0] corresponding to the data group D1 are then stored in output buffers FIFOC0_1 and FIFOC1_1 for the CRC bit output pins DQC0 and DQC1.

CRC bits and data groups thus stored in the output buffers FIFO1_D0, FIFO1_D1, FIFO3_D0, FIFO3_D1, FIFOC0_0, FIFOC0_1, FIFOC1_0, and FIFOC1_1 are output responsive to clock rising edge and falling edge.

Output order is as follows:

data bits D0[38], D0[30], D0[22], and D0[14] are output from the first output buffer FIFO1_D0 to the output pin DQ1;

at the same time, data bits D0[36], D0[28], D0[20], and D0[12] are output from the first output buffer FIFO3_D0 to the output pin DQ3 in the right side region (RIGHT) of the chip; and

CRC bits C0[7], C0[5], C0[3], and C0[1] are output from the output pin DQC0 in the central region of the chip.

After that, data bits D1[38], D1[30], D1[22], and D1[14] are output from the second output buffer FIFO1_D1 to the output pin DQ1 in the left side region (LEFT) of the chip;

at the same time, data bits D1[36], D1[28], D1[20], and D1[12] are output from the second output buffer FIFO3_D1 to the output pin DQ3 in the right side region (RIGHT) of the chip; and

CRC bits C1[7], C1[5], C1[3], and C1[1] are output from the output pin DQC0 in the central region of the chip.

Effects and features of the present exemplary embodiment will be described. In the present exemplary embodiment, similar to the abovementioned second exemplary embodiment, in a chip handling the ×4 and ×8 configurations, in correspondence with data output order in which data output from DQ0 and DQ1, or DQ2 and DQ3, in the ×4 configuration, are output from DQ0, DQ1, DQ4, and DQ5, or DQ2, DQ3, DQ6, and DQ7, in the ×8 configuration, data addresses inside the chip are made the same between the ×4 and ×8 configurations. DQ4 and DQ5 are arranged adjacent to output pins DQ0 and DQ1, and DQ6 and DQ7 are arranged adjacent to output pins DQ2 and DQ3. Thus, it is possible to use a common CRC encoding circuit, for the ×4 and ×8 configurations, as a result of which chip area is able to be reduced and the number of data buses crossing between left and right of the chip is able to be reduced.

Conversely, in a chip handling the ×4 and ×8 configurations, in a configuration in which DQ4 and DQ5 are arranged adjacent to output pins DQ0 and DQ1, and DQ6 and DQ7 are arranged adjacent to DQ2 and DQ3, by setting a data output order to such an order in which data output from DQ0 and DQ1, or DQ2 and DQ3, in the ×4 configuration, are output from DQ0, DQ1, DQ4, and DQ5, or DQ2, DQ3, DQ6, and DQ7, in the ×8 configuration, it becomes possible to use a common CRC encoding circuit, and to reduce chip area.

Each circuit configuration in the present invention is not limited to those shown in the drawings. If a circuit possesses a similar function, a similar effect can be obtained. Output pin numbers are not limited to 4-bit or 8-bit configurations. Application is also possible to 16-bit and 32-bit configurations. In addition, a similar effect can be obtained by application not only to a chip in which two types of word configuration are implemented but also to a chip in which three or more types of word configuration are implemented.

Modifications and adjustments of the exemplary embodiments and examples are possible within the entire disclosure (including the scope of the claims) of the present invention, and in addition, based on fundamental technological ideas thereof. Moreover, various types of combinations and selections of various disclosed elements are possible within the scope of the claims of the present invention. That is, the invention clearly includes all types of transformations and modifications that may be realized by a person skilled in the field according to the whole disclosure including the scope of the claims and the technological ideas.

What is claimed is:

1. A semiconductor device comprising:
first to fourth output pins; and
an encoding circuit that receives a first data group and a second data group,
wherein the first data group are output from the first output pin in a first word configuration;
the second data group and a third data group are output from the first output pin and the second output pin, respectively, in a second word configuration;
a fourth data group is output from the third output pin in the first word configuration; and
a fifth data group and a sixth data group are output from the third output pin and the fourth output pin, respectively, in the second word configuration, and wherein
distance between the second output pin and the first output pin is shorter than distance between the second output pin and the third output pin; and
distance between the fourth output pin and the third output pin is shorter than distance between the fourth output pin and the first output pin.

2. The semiconductor device according to claim 1, comprising:
a first memory cell array having a plurality of memory cells; and
a second memory cell array having a plurality of memory cells, wherein
the first, second, and third data groups are read out from the first memory cell array, and
the fourth, fifth, and sixth data groups are read out from the second memory cell array.

3. The semiconductor device according to claim 2, wherein the plurality of memory cells arranged at prescribed intersections of a plurality of word lines and a plurality of bit lines.

4. A semiconductor device comprising:
a first memory array having a plurality of memory cells;
first and second data buses which receive data output from the first memory array;
a first encoding circuit having input connected to the first and second data buses;
a second memory array having a plurality of memory cells;
third and fourth data buses which receive data output from the second memory array;
a second encoding circuit having input connected to the third and fourth data buses; and
first to fourth output pins, wherein
in a first word configuration,
data of the first and second data buses are output from the first output pin, and
data of the third and fourth data buses are output from the second output pin; and
in a second word configuration,
data of the first data bus are output from the first output pin,
data of the second data bus are output from the third output pin,
data of the third data bus are output from the second output pin, and
data of the fourth data bus are output from the fourth output pin.

5. The semiconductor device according to claim 4, further comprising:
a third encoding circuit; and
a fourth encoding circuit, wherein
the first encoding circuit produces first, second, third, and fourth codes;
the second encoding circuit produces fifth, sixth, seventh, and eighth codes;
the third encoding circuit receives the first, second, seventh, and eighth codes, and produces first and second error detection codes; and
the fourth encoding circuit receives the third, fourth, fifth, and sixth codes, and produces third and fourth error detection codes, and wherein
in the first word configuration,
the first and second error detection codes are output from the first output pin, and
the third and fourth error detection codes are output from the second output pin; and
in the second word configuration,
the first error detection code is output from the first output pin,
the second error detection code is output from the third output pin,
the third error detection code is output from the second output pin, and
the fourth error detection code is output from the fourth output pin.

6. The semiconductor device according to claim 4, comprising:
a third encoding circuit;
a fourth encoding circuit; and
fifth and sixth output pins, wherein
the first encoding circuit produces first, second, third, and fourth codes;
the second encoding circuit produces fifth, sixth, seventh, and eighth codes;
the third encoding circuit receives the first, second, seventh, and eighth codes, and produces first and second error detection codes; and
the fourth encoding circuit receives the third, fourth, fifth, and sixth codes, and produces third and fourth error detection codes, and wherein
in the first word configuration,
the first, second, third, and fourth error detection codes are output from the fifth output pin; and
in the second word configuration,
the first and second error detection codes are output from the fifth output pin, and
the third and fourth error detection codes are output from the sixth output pin.

7. The semiconductor device according to claim 4, wherein the first and second encoding circuits each comprise
a switch which switches output destination of an encoding operation result according to a selection signal corresponding to the first or second word configurations, respectively.

8. The semiconductor device according to claim 4, wherein
distance between the third output pin and the first output pin is shorter than distance between the third output pin and the second output pin, and
distance between the fourth output pin and the second output pin is shorter than distance between the fourth output pin and the first output pin.

9. The semiconductor device according to claim 4, further comprising
fifth and sixth data buses output from the first memory array and input to the first encoding circuit, wherein
in the first word configuration,
data are output from the first output pin in an order of:
data of the first data bus;
data of the second data bus;
data of the fifth data bus; and
data of the sixth data bus; and
in the second word configuration,
data are output from the first output pin in an order of:
data of the first data bus; and
data of the sixth data bus; and
data are output from the third output pin in an order of:
data of the second data bus; and
data of the fifth data bus.

10. The semiconductor device according to claim 9, further comprising:
seventh and eighth data buses output from the second memory array and input to the second encoding circuit, wherein in the first word configuration,
data are output from the second output pin in an order of:
data of the third data bus;
data of the fourth data bus;
data of the fifth data bus; and
data of the sixth data bus; and
in the second word configuration,
data are output from the second output pin in an order of:
data of the third data bus; and
data of the eighth data bus; and
data are output from the fourth output pin in an order of:
data of the fourth data bus; and
data of the seventh data bus.

11. The semiconductor device according to claim 4, further comprising:
a third encoding circuit; and
a fourth encoding circuit, wherein
the first encoding circuit produces first, second, third, and fourth codes;
the second encoding circuit produces fifth, sixth, seventh, and eighth codes;
the third encoding circuit receives the first, second, seventh, and eighth codes, and produces first and second error detection codes; and
the fourth encoding circuit receives the third, fourth, fifth, and sixth codes, and produces third and fourth error detection codes, and wherein
in the first word configuration,
the first and second error detection codes are output from the first output pin, and
the third and fourth error detection codes are output from the second output pin; and
in the second word configuration,
the first error detection code is output from the first output pin,
the second error detection code is output from the second output pin,
the third error detection code is output from the third output pin, and
the fourth error detection code is output from the fourth output pin.

12. The semiconductor device according to claim 4, comprising:
fifth and sixth data buses output from the first memory array and input to the first encoding circuit, wherein
in the first word configuration,
data are output from the first output pin in an order of:
data of the first data bus;
data of the second data bus;
data of the fifth data bus; and
data of the sixth data bus; and
in the second word configuration,
data are output from the first output pin in an order of:
data of the first data bus; and
data of the fifth data bus; and
data are output from the third output pin in an order of:
data of the second data bus;
and data of the sixth data bus.

13. The semiconductor device according to claim 11, comprising:
seventh and eighth data buses output from the second memory array and input to the second encoding circuit, wherein
in the first word configuration,
data are output from the second output pin in an order of:
data of the third data bus;
data of the fourth data bus;
data of the seventh data bus; and
data of the eighth data bus; and
in the second word configuration,
data are output from the second output pin in an order of:
data of the third data bus; and
data of the seventh data bus; and
data are output from the fourth output pin in an order of:
data of the fourth data bus; and
data of the eighth data bus.

14. The semiconductor device according to claim 4, comprising:
a first data line which transfers data read from the memory array;
a first CRC (Cyclic Redundancy Check) encoding circuit which has an input connected to the first data line, the first CRC encoding circuit producing first and second CRC intermediate calculation results;
a first switch which outputs the first CRC intermediate calculation result to the first data bus;
a second switch which outputs the second CRC intermediate calculation result to the first data bus; and
a second CRC encoding circuit which has an input connected to the first data bus.

15. The semiconductor device according to claim 4, wherein the memory cell includes a dynamic memory element.

16. The semiconductor device according to claim 4, wherein the first encoding circuit which receives data read from a plurality of memory banks of the first memory array and multiplexed by a first multiplexer, and calculates code for error detection; and
the second encoding circuit which receives data read from a plurality of memory banks of the second memory array and multiplexed by a second multiplexer, and calculates code for error detection, the device further comprising:
a third encoding circuit which receives calculation results of the first encoding circuit and the second encoding circuit, and generates first and second error detection codes;
a fourth encoding circuit which receives calculation results of the second encoding circuit and the first encoding circuit, and generates third and fourth error detection codes;
first and second output buffers having inputs commonly connected to output of the first multiplexer and output of the third encoding circuit, and having outputs respectively connected to first and second output terminals corresponding to the first memory array; and
third and fourth output buffers having inputs commonly connected to output of the second multiplexer and output of the fourth encoding circuit, and having outputs respectively connected to third and fourth output terminals corresponding to the second memory array, wherein
first and second data output in sequence from the first output terminal, in a first word configuration, are output in parallel from the first output terminal and the second output terminal, in a second word configuration,
third and fourth data output in sequence from the third output terminal, in a first word configuration, are output in parallel from the third output terminal and the fourth output terminal, in a second word configuration, and
the first and second error detection codes output in sequence from the first output terminal, and the third and fourth error detection codes output in sequence from the third output terminal, in the first word configuration, are output in parallel from the first, second, third, and fourth output terminals, in the second word configuration.

17. The semiconductor device according to claim 4, wherein
the first encoding circuit which receives data read from a plurality of memory banks of the first memory array and multiplexed by a first multiplexer, and which calculates code for error detection; and
the second encoding circuit which data read from a plurality of memory banks of a second memory array and multiplexed by a second multiplexer are supplied, and which calculates code for error detection, the device further comprising:
a third encoding circuit which receives calculation results of the first encoding circuit and the second encoding circuit, and generates first and second error detection codes;
first and second output buffers having inputs commonly connected to output of the first multiplexer, and having outputs respectively connected to first and second output terminals corresponding to the first memory array side;
third and fourth output buffers having inputs commonly connected to output of the second multiplexer, and having outputs respectively connected to third and fourth output terminals corresponding to the second memory array side; and
fifth and sixth output buffers having inputs connected to output of the third encoding circuit, and having outputs respectively connected to error detection code-dedicated first and second output terminals, arranged between the first and second output terminals, and the third and fourth output terminals, wherein
first and second data output in sequence from the first output terminal, in a first word configuration, are output in parallel from the first output terminal and the second output terminal, in a second word configuration,
third and fourth data output in sequence from the third output terminal, in a first word configuration, are output in parallel from the third output terminal and the fourth output terminal, in a second word configuration, and
the first and second error detection codes output in sequence from the error detection code-dedicated first output terminal, in the first word configuration, are output in parallel from the error detection code-dedicated first and second output terminals, in the second word configuration.

18. A data output method of a semiconductor device which includes: a first memory array and a second memory array; first and second data buses which receive data output from the first memory array; a first encoding circuit having input connected to the first and second data buses; third and fourth data buses which receives data output from the second memory array; a second encoding circuit having input connected to the third and fourth data buses; and first to fourth output pins, the method comprising:
in a first word configuration,
outputting, in sequence, data of the first and second data buses, from the first output pin; and
outputting, in sequence, data of the third and fourth data buses, from the second output pin; and
in a second word configuration,
outputting, in parallel,
data of the first data bus from the first output pin;
data of the second data bus from the third output pin;
data of the third data bus from the second output pin; and
data of the fourth data bus from the fourth output pin.

19. The method according to claim 18, wherein the semiconductor device further includes a third encoding circuit and a fourth encoding circuit, the method comprising:
the first encoding circuit producing first, second, third, and fourth codes;
the second encoding circuit producing fifth, sixth, seventh, and eighth codes;
the third encoding circuit receiving the first, second, seventh, and eighth codes, and producing first and second error detection codes; and
the fourth encoding circuit receiving the third, fourth, fifth, and sixth codes, and producing third and fourth error detection codes, the method further comprising:
in the first word configuration,
outputting the first and second error detection codes from the first output pin, in sequence, and
outputting the third and fourth error detection codes from the second output pin, in sequence, and
in the second word configuration,
outputting, in parallel, the first error detection code, the second error detection code, the third error detection code, and the fourth error detection code, from the first output pin, the third output pin, the second output pin, and the fourth output pin, respectively.
